(19) United States
(12) Patent Application Publication
(10) Pub. No.: US 2024/0128965 A1
(43) Pub. Date: Apr. 18, 2024

(54) SEMICONDUCTOR MODULE

(71) Applicant: FUJI ELECTRIC CO., LTD., Kawasaki-shi (JP)

(72) Inventor: Eiji KUROSAWA, Matsumoto-city (JP)

(73) Assignee: FUJI ELECTRIC CO., LTD., Kawasaki-shi (JP)

(21) Appl. No.: 18/236,988

(22) Filed: Aug. 23, 2023

(30) Foreign Application Priority Data
Oct. 14, 2022 (JP) 2022-165768

(51) Int. Cl. H03K 17/082

(52) U.S. Cl. CPC H03K 17/0828

(57) ABSTRACT

A semiconductor module 1 includes an IGBT 31z configured to supply a motor 24 with power, a pre-driver 41z configured to drive the IGBT 31z, a protection unit 42z configured to execute first protection operation protecting the IGBT 31z and the pre-driver 41z from operation in an abnormal state, an IGBT 31db configured to adjust the magnitude of voltage input to the IGBT 31z, a pre-driver 41db configured to drive the IGBT 31db, and a protection unit 42db configured to execute second protection operation protecting the IGBT 31db from operation in an abnormal state, and the protection unit 42db executes the second protection operation when the IGBT 31db is operating in an abnormal state and otherwise does not execute the second protection operation regardless of whether or not the protection unit 42z is executing the first protection operation.

### TECHNICAL FIELD

The present invention relates to a semiconductor module that includes a plurality of switching elements.

### BACKGROUND ART

Intelligent power modules (IPMs) that integrate an insulated gate bipolar transistor (IGBT) for power conversion, a freewheeling diode (FWD) chip, and an integrated circuit (IC) for drive/protection function into one package have been known (e.g., Patent Document 1).

An IPM includes a plurality of IGBTs constituting an upper phase portion, drive/protection ICs configured to drive the plurality of IGBTs, a plurality of IGBTs constituting a lower phase portion, and drive/protection ICs configured to drive the plurality of IGBTs. The drive/protection ICs for the lower phases share a power supply. Thus, when control voltage supplied to the drive/protection ICs for the lower phases is reduced, operation for power supply protection works on all the drive/protection ICs for the lower phases.

### CITATION LIST

### Patent Literature

Patent Document 1: JP 2000-341960 A

### SUMMARY OF INVENTION

### Technical Problem

An IGBT for braking is included in the plurality of IGBTs constituting the lower phase portion. The IGBT for braking is provided to prevent voltage that is supplied to the plurality of IGBTs constituting the upper phase portion and the plurality of IGBTs constituting the lower phase portion from increasing. A drive/protection IC that drives the IGBT for braking also shares a power supply with the drive/protection ICs for the lower phases.

The drive/protection IC for braking is configured to be operable when overcurrent protection operation or chip overheating protection operation works on the drive/protection ICs for the lower phases except the drive/protection IC for braking. However, since the power supply is shared by the drive/protection ICs for the lower phases and the drive/protection IC for braking, power supply protection also works on the drive/protection IC for braking when the power supply protection works on the drive/protection ICs for the lower phases except the drive/protection IC for braking. There is a problem in that when the drive/protection IC for braking cannot operate when protection operation works on at least one of the drive/protection ICs for the upper phases and the lower phases except the drive/protection IC for braking, the IGBT for braking not operating causes regenerative operation not to be able to be performed and voltage (a potential difference between positive electrode-side potential and negative electrode-side potential) supplied to the IGBTs to increase to a voltage higher than a rated voltage.

An object of the present invention is to provide a semiconductor module that is capable of preventing voltage supplied to a switching element from increasing even when protection operation works.

### Solution to Problem

In order to achieve the above-described object, a semiconductor module according to one aspect of the present invention includes a first switching element configured to supply a load with power, a first drive unit configured to drive the first switching element, a first protection unit configured to execute first protection operation protecting the first switching element and the first drive unit from operation in an abnormal state, a second switching element configured to adjust magnitude of voltage input to the first switching unit, a second drive unit configured to drive the second switching element, and a second protection unit configured to execute second protection operation protecting the second switching element from operation in an abnormal state, and the second protection unit executes the second protection operation when the second switching element is operating in an abnormal state and otherwise does not execute the second protection operation regardless of whether or not the first protection unit is executing the first protection operation.

### Advantageous Effects of Invention

The one aspect of the present invention enables voltage input to a switching element to be prevented from increasing even when protection operation works.

### BRIEF DESCRIPTION OF DRAWINGS

FIG. 1 is a block diagram illustrative of an example of a schematic configuration of a semiconductor module according to a first embodiment of the present invention.

FIG. 2 is a circuit diagram illustrative of an example of a schematic configuration of a gate drive unit and a brake unit included in the semiconductor module according to the first embodiment of the present invention.

FIG. 3 is a circuit diagram illustrative of an example of a schematic configuration of a gate drive unit and a brake unit included in a semiconductor module according to a second embodiment of the present invention.

### DESCRIPTION OF EMBODIMENTS

The embodiments of the present invention indicate devices and methods to embody the technical idea of the present invention by way of example, and the technical idea of the present invention does not limit the materials, shapes, structures, arrangements, and the like of the constituent components to those described below. The technical idea of the present invention can be subjected to a variety of alterations within the technical scope prescribed by the claims described in CLAIMS.

### First Embodiment

The following description of a semiconductor module according to a first embodiment of the present invention will be made using an intelligent power module that functions as an inverter device as an example. The semiconductor module according to the first embodiment is applicable to not only the intelligent power module but also an intelligent power module that functions as a converter device, a modular multilevel converter, or the like.

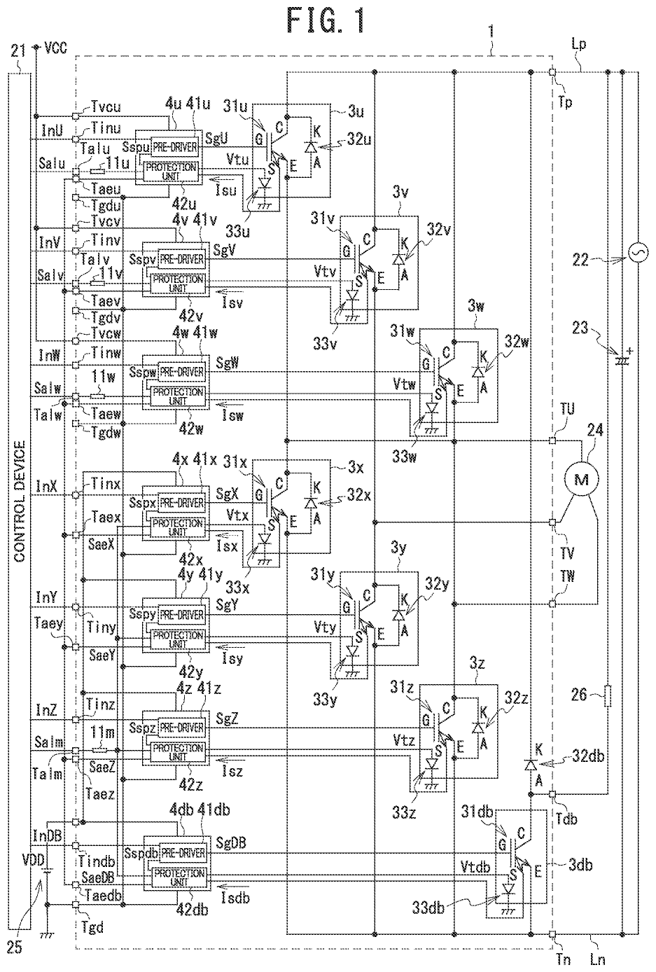

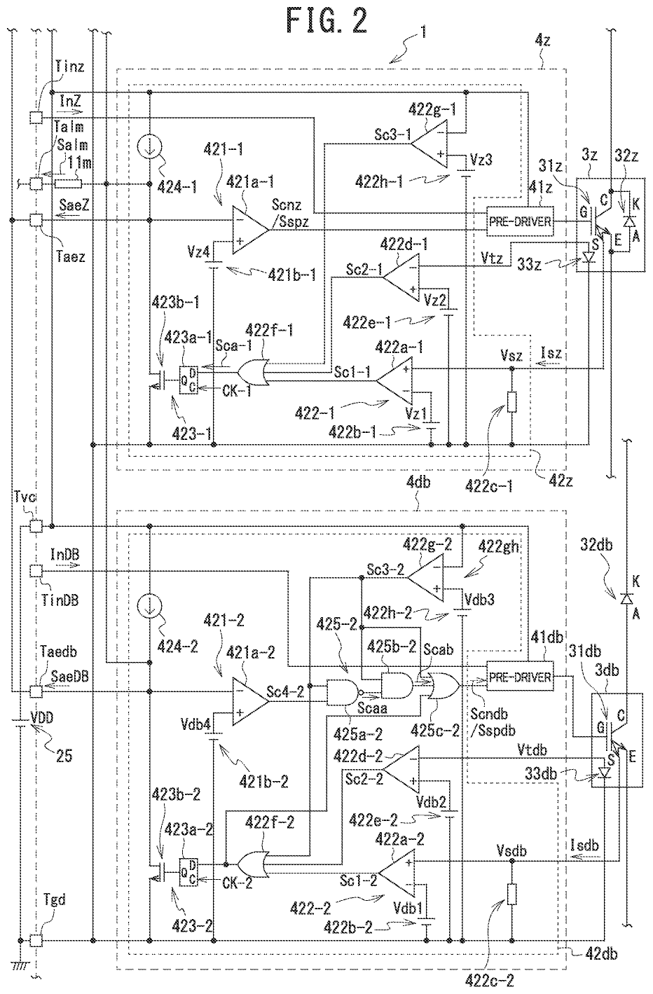

The semiconductor module according to the first embodiment of the present invention will be described using FIGS. 1 and 2. First, an example of an overall configuration of a semiconductor module 1 according to the present embodiment will be described using FIG. 1. FIG. 1 is a block diagram illustrative of an example of a schematic configuration of the semiconductor module 1 according to the present embodiment. In FIG. 1, to facilitate understanding, a control device 21, an AC power supply unit 22, a smoothing capacitor 23, and a motor 24 serving as a drive target that are connected to the semiconductor module 1 are also illustrated.

(Overall Configuration of Semiconductor Module) As illustrated in FIG. 1, the semiconductor module 1 according to the present embodiment is connected to the AC power supply unit 22. The AC power supply unit 22 includes, for example, a three-phase AC power supply (not illustrated) and a rectifier circuit (not-illustrated) configured to full-wave rectify three-phase AC power input from the three-phase AC power supply. The semiconductor module 1 is connected to the smoothing capacitor 23 configured to smooth power rectified by the rectifier circuit. Although illustration of a specific configuration is omitted, the rectifier circuit is, for example, configured by connecting six diodes in a full-bridge configuration or connecting six switching elements in a full-bridge configuration.

A positive electrode-side line Lp is connected to the positive electrode side of the AC power supply unit 22 (i.e., a positive electrode output terminal of the rectifier circuit), and a negative electrode-side line Ln is connected to the negative electrode side of the AC power supply unit 22 (i.e., a negative electrode output terminal of the rectifier circuit). The smoothing capacitor 23 is connected between the positive electrode-side line Lp and the negative electrode-side line Ln. The semiconductor module 1 is configured by an intelligent power module functioning as an inverter device that converts DC voltage applied between the positive electrode-side line Lp and the negative electrode-side line Ln to three-phase (a U phase, a V phase, and a W phase) AC voltage. To the semiconductor module 1, the control device 21 that controls the semiconductor module 1 is connected. The semiconductor module 1 and the control device 21 constitute a power conversion device.

As illustrated in FIG. 1, the semiconductor module 1 has a positive electrode-side power input terminal Tp to which the positive electrode-side line Lp is connected and a negative electrode-side power input terminal Tn that is connected to the negative electrode-side line Ln. The semiconductor module 1 includes a semiconductor element 3u and a semiconductor element 3x that are connected in series between the positive electrode-side power input terminal Tp and the negative electrode-side power input terminal Tn. The semiconductor module 1 includes a semiconductor element 3v and a semiconductor element 3y that are connected in series between the positive electrode-side power input terminal Tp and the negative electrode-side power input terminal Tn. The semiconductor module 1 includes a semiconductor element 3w and a semiconductor element 3z that are connected in series between the positive electrode-side power input terminal Tp and the negative electrode-side power input terminal Tn.

The semiconductor element 3u and the semiconductor element 3x constitute a U-phase output arm. The semiconductor element 3v and the semiconductor element 3y constitute a V-phase output arm. The semiconductor element 3w and the semiconductor element 3z constitute a W-phase output arm. The semiconductor elements 3u, 3v, and 3w are connected to the positive electrode-side line Lp via the positive electrode-side power input terminal Tp and constitute an upper arm (upper phase) portion. The semiconductor elements 3x, 3y, and 3z are connected to the negative electrode-side line Ln via the negative electrode-side power input terminal Tn and constitute a lower arm (lower phase) portion.

The semiconductor element 3u includes an IGBT 31u and a freewheeling diode 32u connected in inverse parallel to the IGBT 31u. Although, in the present embodiment, the IGBT 31u and the freewheeling diode 32u are formed in an identical semiconductor chip, the IGBT 31u and the freewheeling diode 32u may be formed in semiconductor chips different from each other. The semiconductor element 3v includes an IGBT 31v and a freewheeling diode 32v connected in inverse parallel to the IGBT 31v. Although, in the present embodiment, the IGBT 31v and the freewheeling diode 32v are, for example, formed in an identical semiconductor chip, the IGBT 31v and the freewheeling diode 32v may be formed in semiconductor chips different from each other. The semiconductor element 3w includes an IGBT 31w and a freewheeling diode 32w connected in inverse parallel to the IGBT 31w. Although, in the present embodiment, the IGBT 31w and the freewheeling diode 32w are, for example, formed in an identical semiconductor chip, the IGBT 31w and the freewheeling diode 32w may be formed in semiconductor chips different from each other.

Collectors C of the IGBTs 31u, 31v, and 31W and cathodes K of the freewheeling diodes 32u, 32v, and 32w are connected to each other, respectively, and are connected to the positive electrode-side power input terminal Tp. Emitters E of the IGBTs 31u, 31v, and 31W and anodes A of the freewheeling diodes 32u, 32v, and 32w are connected to each other, respectively. Each of the IGBTs 31u, 31v, and 31w has a current detection element S (details will be described later) for detecting current that flows through itself (i.e., the IGBT 31u, 31v, or 31w).

The semiconductor element 3x includes an IGBT 31x and a freewheeling diode 32x connected in inverse parallel to the IGBT 31x. Although, in the present embodiment, the IGBT 31x and the freewheeling diode 32x are formed in an identical semiconductor chip, the IGBT 31x and the freewheeling diode 32x may be formed in semiconductor chips different from each other. The semiconductor element 3y includes an IGBT 31y and a freewheeling diode 32y connected in inverse parallel to the IGBT 31y. Although, in the present embodiment, the IGBT 31y and the freewheeling diode 32y are, for example, formed in an identical semiconductor chip, the IGBT 31y and the freewheeling diode 32y may be formed in semiconductor chips different from each other. The semiconductor element 3z includes an IGBT 31z and a freewheeling diode 32z connected in inverse parallel to the IGBT 31z. Although, in the present embodiment, the IGBT 31z and the freewheeling diode 32z are, for example, formed in an identical semiconductor chip, the IGBT 31z and the freewheeling diode 32z may be formed in semiconductor chips different from each other.

A collector C of the IGBT 31x and a cathode K of the freewheeling diode 32x are connected to each other. The collector C of the IGBT 31x and the cathode K of the freewheeling diode 32x are connected to the emitter E of the IGBT 31u and the anode A of the freewheeling diode 32u. A collector C of the IGBT 31y and a cathode K of the freewheeling diode 32y are connected to the emitter E of the IGBT 31v and the anode A of the freewheeling diode 32v. A collector C of the IGBT 31z and a cathode K of the freewheeling diode 32z are connected to the emitter E of the IGBT 31w and the anode A of the freewheeling diode 32w. Emitters E of the IGBTs 31x, 31y, and 31z and anodes A of the freewheeling diodes 32x, 32y, and 32z are connected to each other, respectively, and are connected to the negative electrode-side power input terminal Tn. Each of the IGBTs 31x, 31y, and 31z has a current detection element S (details will be described later) for detecting current that flows through itself (i.e., the IGBT 31x, 31y, or 31z).

The semiconductor element 3u includes a temperature detection element 33u that is formed by a diode formed of, for example, silicon. An anode of the temperature detection element 33u is connected to a protection unit 42u (details will be described later), and a cathode of the temperature detection element 33u is connected to a reference potential terminal (for example, a ground terminal). The semiconductor element 3v includes a temperature detection element 33v that is formed by a diode formed of, for example, silicon. An anode of the temperature detection element 33v is connected to a protection unit 42v (details will be described later), and a cathode of the temperature detection element 33v is connected to the reference potential terminal (for example, the ground terminal). The semiconductor element 3w includes a temperature detection element 33w that is formed by a diode formed of, for example, silicon. An anode of the temperature detection element 33w is connected to a protection unit 42w (details will be described later), and a cathode of the temperature detection element 33w is connected to the reference potential terminal (for example, the ground terminal).

The semiconductor element 3x includes a temperature detection element 33x that is formed by a diode formed of, for example, silicon. An anode of the temperature detection element 33x is connected to a protection unit 42x (details will be described later), and a cathode of the temperature detection element 33x is connected to the reference potential terminal (for example, the ground terminal). The semiconductor element 3y includes a temperature detection element 33y that is formed by a diode formed of, for example, silicon. An anode of the temperature detection element 33y is connected to a protection unit 42y (details will be described later), and a cathode of the temperature detection element 33y is connected to the reference potential terminal (for example, the ground terminal). The semiconductor element 3z includes a temperature detection element 33z that is formed by a diode formed of, for example, silicon. An anode of the temperature detection element 33z is connected to a protection unit 42z (details will be described later), and a cathode of the temperature detection element 33z is connected to the reference potential terminal (for example, the ground terminal).

Although details will be described later, the semiconductor module 1 detects temperatures of the IGBTs 31u, 31v, 31w, 31x, 31y, and 31z by making use of characteristics that forward voltages of the temperature detection elements 33u, 33v, 33w, 33x, 33y, and 33z change according to temperatures, respectively.

The emitter E of the IGBT 31u, the anode A of the freewheeling diode 32u, the collector C of the IGBT 31x, and the cathode K of the freewheeling diode 32x are connected to a U-phase output terminal TU. The U-phase output terminal TU is a terminal to which U-phase AC voltage that the semiconductor module 1 generates by DC-AC converting the DC voltage input from the AC power unit 22 is output.

The emitter E of the IGBT 31v, the anode A of the freewheeling diode 32v, the collector C of the IGBT 31y, and the cathode K of the freewheeling diode 32y are connected to a V-phase output terminal TV. The V-phase output terminal TV is a terminal to which V-phase AC voltage that the semiconductor module 1 generates by DC-AC converting the DC voltage input from the AC power unit 22 is output.

The emitter E of the IGBT 31w, the anode A of the freewheeling diode 32w, the collector C of the IGBT 31z, and the cathode K of the freewheeling diode 32z are connected to a W-phase output terminal TW. The W-phase output terminal TW is a terminal to which W-phase AC voltage that the semiconductor module 1 generates by DC-AC converting the DC voltage input from the AC power unit 22 is output.

As illustrated in FIG. 1, for example, the motor 24 that serves as a load is connected to the U-phase output terminal TU, the V-phase output terminal TV, and the W-phase output terminal TW that are disposed to the semiconductor module 1. Thus, the emitters E of the IGBTs 31u, 31v, and 31w and the anodes A of the freewheeling diodes 32u, 32v, and 32w that are disposed in the semiconductor elements 3u, 3v, and 3w, respectively, and the collectors C of the IGBTs 31x, 31y, and 31z and the cathodes K of the freewheeling diodes 32x, 32y, and 32z that are disposed in the semiconductor elements 3x, 3y, and 3z, respectively, are connected to the motor 24.

As described above, the semiconductor module 1 includes the IGBTs 31u, 31v, 31w, 31x, 31y, and 31z (examples of a first switching element) configured to supply the motor (an example of a load) 24 with power. Although, in the present embodiment, the semiconductor module 1 includes IGBTs as first switching elements, the semiconductor module 1 may include another type of power semiconductor element, such as a power metal-oxide-semiconductor field-effect transistor (MOSFET).

As illustrated in FIG. 1, the semiconductor module 1 includes a pre-driver 41u (an example of a first drive unit) configured to drive the IGBT 31u, a pre-driver 41v (another example of the first drive unit) configured to drive the IGBT 31v, and a pre-driver 41w (still another example of the first drive unit) configured to drive the IGBT 31w. An output of the pre-driver 41u is connected to a gate G of the IGBT 31u. An output of the pre-driver 41v is connected to a gate G of the IGBT 31v. An output of the pre-driver 41w is connected to a gate G of the IGBT 31w.

The semiconductor module 1 includes a pre-driver 41x (still another example of the first drive unit) configured to drive the IGBT 31x, a pre-driver 41y (still another example of the first drive unit) configured to drive the IGBT 31y, and a pre-driver 41z (still another example of the first drive unit) configured to drive the IGBT 31z. An output of the pre-driver 41x is connected to a gate G of the IGBT 31x. An output of the pre-driver 41y is connected to a gate G of the IGBT 31y. An output of the pre-driver 41z is connected to a gate G of the IGBT 31z.

The semiconductor module 1 includes the protection unit 42u (an example of a first protection unit) configured to execute a first protection operation (details will be described later) of protecting the IGBT 31u and the pre-driver 41u from operation in an abnormal state. The semiconductor module 1 includes the protection unit 42v (another example of the first protection unit) configured to execute a first protection operation (details will be described later) of protecting the IGBT 31v and the pre-driver 41v from operation in an abnormal state. The semiconductor module 1 includes the protection unit 42w (still another example of the first protection unit) configured to execute a first protection operation (details will be described later) of protecting the IGBT 31w and the pre-driver 41w from operation in an abnormal state.

The semiconductor module 1 includes the protection unit 42x (still another example of the first protection unit) configured to execute a first protection operation (details will be described later) of protecting the IGBT 31x and the pre-driver 41x from operation in an abnormal state. The semiconductor module 1 includes the protection unit 42y (still another example of the first protection unit) configured to execute a first protection operation (details will be described later) of protecting the IGBT 31y and the pre-driver 41y from operation in an abnormal state. The semiconductor module 1 includes the protection unit 42z (still another example of the first protection unit) configured to execute a first protection operation (details will be described later) of protecting the IGBT 31z and the pre-driver 41z from operation in an abnormal state.

To the protection units 42u, 42v, 42w, 42x, 42y, and 42z, the current detection elements S of the IGBTs 31u, 31v, 31w, 31x, 31y, and 31z and the temperature detection elements 33u, 33v, 33w, 33x, 33y, and 33z disposed in the semiconductor elements 3u, 3v, 3w, 3x, 3y, and 3z are connected, respectively.

In the operation in an abnormal state of the IGBTs 31u, 31v, 31w, 31x, 31y, and 31z, operation in an overcurrent condition and operation in a high-temperature condition of the IGBTs 31u, 31v, 31w, 31x, 31y, and 31z are included. Although details will be described later, the protection units 42u, 42v, 42w, 42x, 42y, and 42z detect the overcurrent condition, using detected currents Isu, Isv, Isw, Isx, Isy, and Isz that are input from the current detection elements S, respectively. The protection units 42u, 42v, 42w, 42x, 42y, and 42z detect the high-temperature condition, using detected voltages Vtu, Vtv, Vtw, Vtx, Vty, and Vtz that are input from the temperature detection elements 33u, 33v, 33w, 33x, 33y, and 33z, respectively.

In the operation in an abnormal state of the pre-drivers 41u, 41v, 41w, 41x, 41y, and 41z, operation in a state in which power supply voltage VCC for the pre-drivers 41u, 41v, 41w, 41x, 41y, and 41z to operate is lower than a predetermined voltage (a voltage higher than an absolute minimum rated voltage) at which the pre-drivers 41u, 41v, 41w, 41x, 41y, and 41z can operate is included. Although details will be described later, each of the protection units 42u, 42v, 42w, 42x, 42y, and 42z includes a comparator 422g-1 (not illustrated in FIG. 1, see FIG. 2) serving as a determination unit that determines a voltage level of the power supply voltage VCC that is input from the outside of the semiconductor module 1 and is configured to monitor the voltage level of the power supply voltage VCC.

In the first protection operation, generation and output of, when at least one of the IGBTs 31u, 31v, 31w, 31x, 31y, and 31z is operating in an abnormal state or when at least one of the pre-drivers 41u, 41v, 41w, 41x, 41y, and 41z is operating in an abnormal state, a protection signal SaeU, SaeV, SaeW, SaeX, SaeY, or SaeZ corresponding to an IGBT or a pre-driver that is abnormally operating are included. For example, when the IGBT 31z is operating in an abnormal state, the protection unit 42z disposed in a gate drive unit 4z generates and outputs the protection signal SaeZ. Details of the protection signals SaeU, SaeV, SaeW, SaeX, SaeY, and SaeZ will be described later.

The pre-driver 41u and the protection unit 42u constitute a gate drive unit 4u, the pre-driver 41v and the protection unit 42v constitute a gate drive unit 4v, and the pre-driver 41w and the protection unit 42w constitute a gate drive unit 4w. Thus, the semiconductor module 1 includes the gate drive unit 4u including the pre-driver 41u and the protection unit 42u, the gate drive unit 4v including the pre-driver 41v and the protection unit 42v, and the gate drive unit 4w including the pre-driver 41w and the protection unit 42w.

The pre-driver 41x and the protection unit 42x constitute a gate drive unit 4x, the pre-driver 41y and the protection unit 42y constitute a gate drive unit 4y, and the pre-driver 41z and the protection unit 42z constitute the gate drive unit 4z. Thus, the semiconductor module 1 includes the gate drive unit 4x including the pre-driver 41x and the protection unit 42x, the gate drive unit 4y including the pre-driver 41y and the protection unit 42y, and the gate drive unit 4z including the pre-driver 41z and the protection unit 42z.

Each of the gate drive units 4u, 4v, 4w, 4x, 4y, and 4z corresponds to a drive/protection circuit. Specific configurations of the gate drive units 4u, 4v, 4w, 4x, 4y, and 4z will be described later.

As illustrated in FIG. 1, the semiconductor module 1 includes an IGBT 31db (an example of a second switching element) that is disposed in a semiconductor element 3db and configured to adjust the magnitude of voltage that is input to the IGBTs 31u, 31v, 31w, 31x, 31y, and 31z (i.e., the DC voltage input from the AC power unit 22). The semiconductor module 1 includes a freewheeling diode 32db that is connected to the IGBT 31db.

Specifically, a collector C of the IGBT 31db is connected to an anode A of the freewheeling diode 32db. An emitter E of the IGBT 31db is connected to the negative electrode-side power input terminal Tn. A cathode K of the freewheeling diode 32db is connected to the positive electrode-side power input terminal Tp. Thus, the freewheeling diode 32db and the IGBT 31db are connected in series between the positive electrode-side power input terminal Tp and the negative electrode-side power input terminal Tn. Note that the emitter E of the IGBT 31db is also connected to the emitter E of each of the IGBTs 31x, 31y, and 31z and the anode A of each of the freewheeling diodes 32x, 32y, and 32z. The cathode K of the freewheeling diode 32db is also connected to the collector C of each of the IGBTs 31u, 31v, and 31W and a cathode K of each of the freewheeling diodes 32u, 32v, and 32w.

The IGBT 31db has a current detection element S (details will be described later) for detecting current that flows through itself (i.e., the IGBT 31db). In addition, the semiconductor element 3db includes a temperature detection element 33db that is formed by a diode formed of, for example, silicon. An anode of the temperature detection element 33db is connected to a protection unit 42db (details will be described later), and a cathode of the temperature detection element 33db is connected to the reference potential terminal (e.g., the ground terminal). Although details will be described later, the semiconductor module 1 detects temperature of the IGBT 31db by making use of characteristics that forward voltage of the temperature detection element 33db changes according to temperature.

As illustrated in FIG. 1, the semiconductor module 1 includes a pre-driver 41db (an example of a second drive unit) configured to drive the IGBT 31db and the protection unit 42db (an example of a second protection unit) configured to execute a second protection operation that protects the IGBT 31db from operation in an abnormal state. To the protection unit 42db, the current detection elements S of the IGBT 31db and the temperature detection element 33db that is disposed in the semiconductor element 3db are connected.

In the operation in an abnormal state of the IGBT 31db, operation in an overcurrent condition and operation in a high-temperature condition of the IGBT 31db are included. Although details will be described later, the protection unit 42db detects the overcurrent condition, using detected current Isdb that is input from the current detection element S of the IGBT 31db. The protection units 42db detects the high-temperature condition, using detected voltages Vtdb that is input from the temperature detection element 33db.

In the present embodiment, the protection unit 42db is configured to execute the second protection operation in order to, in addition to protecting the IGBT 31db, protect the pre-driver 41db from operation in an abnormal state. In the operation in an abnormal state of the pre-driver 41db, operation in a state in which power supply voltage VDD for the pre-driver 41db to operate is lower than a minimum voltage at which the pre-driver 41db can operate is included. Although details will be described later, the protection unit 42db includes a comparator 422g-2 (not illustrated in FIG. 1, see FIG. 2) serving as a determination unit that determines a voltage level of the power supply voltage VDD that is input from the outside of the semiconductor module 1 and is configured to monitor the voltage level of the power supply voltage VDD.

In the present embodiment, in the second protection operation, generation and output of a protection signal SaeDB when the IGBT 31db is operating in an abnormal state or when the pre-driver 41db is operating in an abnormal state are included. Details of the protection signal SaeDB will be described later.

The pre-driver 41db and the protection unit 42db constitute a brake unit 4db. Thus, the semiconductor module 1 includes the brake unit 4db including the pre-driver 41db and the protection unit 42db.

As illustrated in FIG. 1, the semiconductor module 1 includes a regenerative power terminal Tdb. The regenerative power terminal Tdb is connected to the collector C of the IGBT 31db and the anode of the freewheeling diode 32db. Between the regenerative power terminal Tdb and the positive electrode-side power input terminal Tp, a resistance element 26 is connected. One terminal of the resistance element 26 is connected to the positive electrode-side power input terminal Tp, and the other terminal of the resistance element 26 is connected to the regenerative power terminal Tdb. Thus, the resistance element 26 is connected in parallel with the freewheeling diode 32db between the regenerative power terminal Tdb and the positive electrode-side power input terminal Tp. The resistance element 26 is connected in series with the IGBT 31db between the positive electrode-side power input terminal Tp and the negative electrode-side power input terminal Tn.

The control device 21 monitors potential at each of the positive electrode-side power input terminal Tp and the negative electrode-side power input terminal Tn. When a potential difference between the positive electrode-side power input terminal Tp and the negative electrode-side power input terminal Tn, that is, voltage input to each of the series-connected IGBT 31u and IGBT 31x, the series-connected IGBT 31v and IGBT 31y, and the series-connected IGBT 31w and IGBT 31z, exceeds a predetermined value (for example, a voltage value of rated voltage), the control device 21 outputs an input signal InDB (details will be described later) the signal level of which alternates between a high level and a low level with a predetermined period to the pre-driver 41db that drives the IGBT 31db. The pre-driver 41db intermittently brings the IGBT 31db into a conducting state and causes regenerative current sent from the motor 24 to the AC power unit 22 side to bypass the AC power unit 22 and be consumed via the resistance element 26. By this configuration, the semiconductor module 1 is capable of preventing the potential difference between the positive electrode-side power input terminal Tp and the negative electrode-side power input terminal Tn from exceeding the rated voltage and preventing a dielectric breakdown from occurring to the IGBTs 31u, 31v, 31w, 31x, 31y, and 31z.

Although details will be described later, the protection unit 42db executes the second protection operation when the IGBT 31db is operating in an abnormal state and otherwise does not execute the second protection operation regardless of whether or not the protection units 42u, 42v, 42w, 42x, 42y, and 42z are executing the first protection operation. By this configuration, in the semiconductor module 1, even when at least one of the IGBTs 31u, 31v, 31w, 31x, 31y, and 31z and the pre-drivers 41u, 41v, 41w, 41x, 41y, and 41z is operating in an abnormal state, the protection unit 42db disposed in the brake unit 4db does not execute the second protection operation, and the IGBT 31db thus continues regular operation. As a result, the semiconductor module 1 is capable of preventing voltage that is input to the IGBTs 31u, 31v, 31w, 31x, 31y, and 31z from increasing even when the protection operation works.

On the other hand, when at least either the IGBTs 31u, 31v, 31w, 31x, 31y, and 31z or the pre-drivers 41u, 41v, 41w, 41x, 41y, and 41z are operating in an abnormal state or when the protection unit 42db is executing the second protection operation, the protection units 42u, 42v, 42w, 42x, 42y, and 42z that are disposed in the gate drive units 4u, 4v, 4w, 4x, 4y, and 4z execute the first protection operation, respectively. By this configuration, the semiconductor module 1 is capable of executing the first protection operation when at least one of the IGBTs 31u, 31v, 31w, 31x, 31y, 31z, and 31db and the pre-drivers 41u, 41v, 41w, 41x, 41y, 41z, and 41db is operating in an abnormal state and suspending operation of each of the IGBTs 31u, 31v, 31w, 31x, 31y, and 31z regardless of whether or not the IGBT is in an abnormal state. As a result, since the semiconductor module 1 is capable of suspending operation in an overcurrent condition or operation in a high-temperature condition of the IGBTs 31u, 31v, 31w, 31x, 31y, and 31z, the semiconductor module 1 is capable of preventing the IGBTs 31u, 31v, 31w, 31x, 31y, and 31z from breaking down.

As illustrated in FIG. 1, the semiconductor module 1 includes power input terminals Tvcu, Tvcv, and Tvcw to which the power supply voltage VCC is input. The power input terminals Tvcu, Tvcv, and Tvcw are connected to the gate drive units 4u, 4v, and 4w, respectively. By this configuration, to the gate drive units 4u, 4v, and 4w, the power supply voltage VCC is input via the power input terminals Tvcu, Tvcv, and Tvcw, respectively.

The semiconductor module 1 includes upper-phase reference potential terminals Tgdu, Tgdv, and Tgdw. The upper-phase reference potential terminals Tgdu, Tgdv, and Tgdw are connected to the gate drive units 4u, 4v, and 4w, respectively. By this configuration, reference potentials of the pre-drivers 41u, 41v, and 41w and the protection units 42u, 42v, and 42w that are disposed in the gate drive units 4u, 4v, and 4w, respectively, are set to the same potential.

The semiconductor module 1 includes a power input terminal Tvc. The power input terminal Tvc is connected to the gate drive units 4x, 4y, and 4z and the brake unit 4db by wiring formed inside the semiconductor module 1. By this configuration, the gate drive units 4x, 4y, and 4z and the brake unit 4db share power supply voltage.

The semiconductor module 1 includes a reference potential terminal Tgd. The reference potential terminal Tgd is connected to the gate drive units 4x, 4y, and 4z and the brake unit 4db by wiring formed inside the semiconductor module 1. By this configuration, reference potentials of the gate drive units 4x, 4y, and 4z and the brake unit 4db are set to the same potential.

The reference potential terminal Tgd is connected to, for example, the ground (GND) as the reference potential. Between the power input terminal Tvc and the reference potential terminal Tgd, a constant voltage source 25 is connected. The positive electrode side of the constant voltage source 25 is connected to the power input terminal Tvc, and, to the negative electrode side of the constant voltage source 25, the reference potential terminal Tgd is connected. Thus, between the power input terminal Tvc and the reference potential terminal Tgd, power supply voltage VDD that the constant voltage source 25 generates is applied. Therefore, to the gate drive units 4x, 4y, and 4z and the brake unit 4db, the power supply voltage VDD that the constant voltage source 25 generates is input via the power input terminal Tvc and the reference potential terminal Tgd. Thus, the gate drive units 4x, 4y, and 4z and the brake unit 4db operates using the constant voltage source 25 as a power supply. The power supply voltage VDD, for example, has the same voltage value as the power supply voltage VCC.

The reference potential terminal Tgd is connected to the upper-phase reference potential terminals Tgdu, Tgdv, and Tgdw by wiring formed inside the semiconductor module 1. By this configuration, the gate drive units 4u, 4v, and 4w, the gate drive units 4x, 4y, and 4z, and the brake unit 4db are set to the same potential (e.g., the ground potential). In addition, by setting voltage that the constant voltage source 25 outputs to the same voltage as the power supply voltage VCC, the gate drive units 4u, 4v, and 4w, the gate drive units 4x, 4y, and 4z, and the brake unit 4db operate at power supply voltages having the same voltage value.

As illustrated in FIG. 1, the gate drive unit 4u is connected to a signal input terminal TinU that is disposed to the semiconductor module 1. The signal input terminal TinU is connected to the control device 21. By this configuration, an input signal InU that is output from the control device 21 is input to the pre-driver 41u that is disposed in the gate drive unit 4u via the signal input terminal TinU. The pre-driver 41u generates a gate drive signal SgU for driving the IGBT 31u, using the input signal InU. The gate drive signal SgU that is output from the pre-driver 41u is input to the gate G of the IGBT 31u.

The gate drive unit 4v is connected to a signal input terminal TinV that is disposed to the semiconductor module 1. The signal input terminal TinV is connected to the control device 21. By this configuration, an input signal InV that is output from the control device 21 is input to the pre-driver 41v that is disposed in the gate drive unit 4v via the signal input terminal TinV. The pre-driver 41v generates a gate drive signal SgV for driving the IGBT 31v, using the input signal InV. The gate drive signal SgV that is output from the pre-driver 41v is input to the gate G of the IGBT 31v.

The gate drive unit 4w is connected to a signal input terminal TinW that is disposed to the semiconductor module 1. The signal input terminal TinW is connected to the control device 21. By this configuration, an input signal InW that is output from the control device 21 is input to the pre-driver 41w that is disposed in the gate drive unit 4w via the signal input terminal TinW. The pre-driver 41w generates a gate drive signal SgW for driving the IGBT 31w, using the input signal InW. The gate drive signal SgW that is output from the pre-driver 41w is input to the gate G of the IGBT 31w.

The gate drive unit 4x is connected to a signal input terminal TinX that is disposed to the semiconductor module 1. The signal input terminal TinX is connected to the control device 21. By this configuration, an input signal InX that is output from the control device 21 is input to the pre-driver 41x that is disposed in the gate drive unit 4x via the signal input terminal TinX. The pre-driver 41x generates a gate drive signal SgX for driving the IGBT 31x, using the input signal InX. The gate drive signal SgX that is output from the pre-driver 41x is input to the gate G of the IGBT 31x.

The gate drive unit 4y is connected to a signal input terminal TinY that is disposed to the semiconductor module 1. The signal input terminal TinY is connected to the control device 21. By this configuration, an input signal InY that is output from the control device 21 is input to the pre-driver 41y that is disposed in the gate drive unit 4y via the signal input terminal TinY. The pre-driver 41y generates a gate drive signal SgY for driving the IGBT 31y, using the input signal InY. The gate drive signal SgY that is output from the pre-driver 41y is input to the gate G of the IGBT 31y.

The gate drive unit 4z is connected to a signal input terminal TinZ that is disposed to the semiconductor module 1. The signal input terminal TinZ is connected to the control device 21. By this configuration, an input signal InZ that is output from the control device 21 is input to the pre-driver 41z that is disposed in the gate drive unit 4z via the signal input terminal TinZ. The pre-driver 41z generates a gate drive signal SgZ for driving the IGBT 31z, using the input signal InZ. The gate drive signal SgZ that is output from the pre-driver 41z is input to the gate G of the IGBT 31z.

The brake unit 4db is connected to a signal input terminal TinDB that is disposed to the semiconductor module 1. The signal input terminal TinDB is connected to the control device 21. By this configuration, the input signal InDB that is output from the control device 21 is input to the pre-driver 41db that is disposed in the brake unit 4db via the signal input terminal TinDB. The pre-driver 41db generates a brake drive signal SgDB for driving the IGBT 31db, using the input signal InDB. The brake drive signal SgDB that is output from the pre-driver 41db is input to the gate G of the IGBT 31db.

As illustrated in FIG. 1, the semiconductor module 1 includes signal detection terminals Taeu, Taev, Taew, Taex, Taey, and Taez (examples of a first signal detection terminal) that are connected to the protection units 42u, 42v, 42w, 42x, 42y, and 42z, respectively, and detect the protection signal SaeDB (an example of a second protection signal) that indicates whether or not the second protection operation is executed. Thus, the semiconductor module 1 includes a plurality of pairs of the protection units 42u, 42v, 42w, 42x, 42y, and 42z and the signal detection terminals Taeu, Taev, Taew, Taex, Taey, and Taez. The protection unit 42u and the signal detection terminal Taeu pair with each other (i.e., are connected to each other), the protection unit 42v and the signal detection terminal Taev pair with each other (i.e., are connected to each other), and the protection unit 42w and the signal detection terminal Taew pair with each other (i.e., are connected to each other). The protection unit 42x and the signal detection terminal Taex pair with each other (i.e., are connected to each other), the protection unit 42y and the signal detection terminal Taey pair with each other (i.e., are connected to each other), and the protection unit 42z and the signal detection terminal Taez pair with each other (i.e., are connected to each other).

Although details will be described later, each of the signal detection terminals Taeu, Taev, Taew, Taex, Taey, and Taez also detects the protection signals SaeU, SaeV, SaeW, SaeX, SaeY, and SaeZ (examples of a first protection signal) based on the first protection operation in remaining ones of the protection units 42u, 42v, 42w, 42x, 42y, and 42z other than a protection unit with which the signal detection terminal pairs. Specifically, the signal detection terminal Taeu also detects the protection signals SaeV, SaeW, SaeX, SaeY, and SaeZ based on the first protection operation in the protection units 42v, 42w, 42x, 42y, and 42z with which the signal detection terminal itself (i.e., the signal detection terminal Taeu) does not pair.

The signal detection terminal Taev also detects the protection signals SaeU, SaeW, SaeX, SaeY, and SaeZ based on the first protection operation in the protection units 42u, 42w, 42x, 42y, and 42z with which the signal detection terminal itself (i.e., the signal detection terminal Taev) does not pair. The signal detection terminal Taew also detects the protection signals SaeU, SaeV, SaeX, SaeY, and SaeZ based on the first protection operation in the protection units 42u, 42v, 42x, 42y, and 42z with which the signal detection terminal itself (i.e., the signal detection terminal Taew) does not pair.

The signal detection terminal Taex also detects the protection signals SaeU, SaeV, SaeW, SaeY, and SaeZ based on the first protection operation in the protection units 42u, 42v, 42w, 42y, and 42z with which the signal detection terminal itself (i.e., the signal detection terminal Taex) does not pair. The signal detection terminal Taey also detects the protection signals SaeU, SaeV, SaeW, SaeX, and SaeZ based on the first protection operation in the protection units 42u, 42v, 42w, 42x, and 42z with which the signal detection terminal itself (i.e., the signal detection terminal Taey) does not pair. The signal detection terminal Taez also detects the protection signals SaeU, SaeV, SaeW, SaeX, and SaeY based on the first protection operation in the protection units 42u, 42v, 42w, 42x, and 42y with which the signal detection terminal itself (i.e., the signal detection terminal Taez) does not pair.

The semiconductor module 1 includes a signal detection terminal Taedb (an example of a second signal detection terminal) that is connected to the signal detection terminals Taeu, Taev, Taew, Taex, Taey, and Taez and the protection unit 42db and detects the protection signals SaeU, SaeV, SaeW, SaeX, SaeY, and SaeZ (examples of the first protection signal) that indicates whether or not the first protection operation is executed.

The protection units 42u, 42v, 42w, 42x, 42y, and 42z output the protection signals SaeU, SaeV, SaeW, SaeX, SaeY, and SaeZ to the signal detection terminals Taeu, Taev, Taew, Taex, Taey, and Taez, respectively, and the protection unit 42db outputs the protection signal SaeDB to the signal detection terminal Taedb. The signal detection terminals Taeu, Taev, Taew, Taex, Taey, Taez, and Taedb are interconnected by wiring that is disposed outside the semiconductor module 1 (such as wire wiring and pattern wiring formed on a printed circuit board on which the semiconductor module 1 is mounted).

Thus, the protection signal SaeU output from the protection unit 42u is input to the signal detection terminal Taev, Taew, Taex, Taey, Taez, and Taedb via the signal detection terminal Taeu and the wiring. The protection signal SaeV output from the protection unit 42v is input to the signal detection terminal Taeu, Taew, Taex, Taey, Taez, and Taedb via the signal detection terminal Taev and the wiring. The protection signal SaeW output from the protection unit 42w is input to the signal detection terminal Taeu, Taev, Taex, Taey, Taez, and Taedb via the signal detection terminal Taew and the wiring.

The protection signal SaeX output from the protection unit 42x is input to the signal detection terminal Taeu, Taev, Taew, Taey, Taez, and Taedb via the signal detection terminal Taex and the wiring. The protection signal SaeY output from the protection unit 42y is input to the signal detection terminal Taeu, Taev, Taew, Taex, Taez, and Taedb via the signal detection terminal Taey and the wiring. The protection signal SaeZ output from the protection unit 42z is input to the signal detection terminal Taeu, Taev, Taew, Taex, Taey, and Taedb via the signal detection terminal Taez and the wiring. The protection signal SaeDB output from the protection unit 42db is input to the signal detection terminal Taeu, Taev, Taew, Taex, Taey, and Taez via the signal detection terminal Taedb and the wiring.

By this configuration, the signal detection terminal Taeu can detect the protection signals SaeV, SaeW, SaeX, SaeY, SaeZ, and SaeDB that are output from the protection units 42v, 42w, 42x, 42y, 42z, and 42db, respectively. The signal detection terminal Taev can detect the protection signals SaeU, SaeW, SaeX, SaeY, SaeZ, and SaeDB that are output from the protection units 42u, 42w, 42x, 42y, 42z, and 42db, respectively. The signal detection terminal Taew can detect the protection signals SaeU, SaeV, SaeX, SaeY, SaeZ, and SaeDB that are output from the protection units 42u, 42v, 42x, 42y, 42z, and 42db, respectively.

In addition, the signal detection terminal Taex can detect the protection signals SaeU, SaeV, SaeW, SaeY, SaeZ, and SaeDB that are output from the protection units 42u, 42v, 42w, 42y, 42z, and 42db, respectively. The signal detection terminal Taey can detect the protection signals SaeU, SaeV, SaeW, SaeX, SaeZ, and SaeDB that are output from the protection units 42u, 42v, 42w, 42x, 42z, and 42db, respectively. The signal detection terminal Taez can detect the protection signals SaeU, SaeV, SaeW, SaeX, SaeY, and SaeDB that are output from the protection units 42u, 42v, 42w, 42x, 42y, and 42db, respectively. The signal detection terminal Taedb can detect the protection signals SaeU, SaeV, SaeW, SaeX, SaeY, and SaeZ that are output from the protection units 42u, 42v, 42w, 42x, 42y, and 42z, respectively.

Although details will be described later, each of the protection units 42u, 42v, 42w, 42x, 42y, and 42z executes the first protection operation when one of the signal detection terminals Taeu, Taev, Taew, Taex, Taey, and Taez that pairs with the protection unit detects one of the protection signals SaeU, SaeV, SaeW, SaeX, SaeY, SaeZ, and SaeDB that is output from corresponding one of the protection units 42u, 42v, 42w, 42x, 42y, 42z, and 42db other than the protection unit its self. Thus, the semiconductor module 1 is capable of, when at least one of the protection units 42u, 42v, 42w, 42x, 42y, 42z, and 42db and the IGBTs 31u, 31v, 31w, 31x, 31y, 31z, and 31db is operating in an abnormal state, suspending operation of remaining ones of the protection units 42u, 42v, 42w, 42x, 42y, and 42z and IGBTs 31u, 31v, 31w, 31x, 31y, and 31z other than the protection unit or the IGBT operating in an abnormal state. By this configuration, the semiconductor module 1 is capable of preventing a situation in which, under the influence of one of the protection units 42u, 42v, 42w, 42x, 42y, 42z, and 42db and the IGBTs 31u, 31v, 31w, 31x, 31y, 31z, and 31db that is operating in an abnormal state, remaining ones of the protection units 42u, 42v, 42w, 42x, 42y, and 42z and IGBTs 31u, 31v, 31w, 31x, 31y, and 31z other than the protection unit or the IGBT operating in an abnormal state that are operating in a normal state are forced to operate in an abnormal state.

In addition, although details will be described later, even when the signal detection terminal Taedb detects one of the protection signals SaeU, SaeV, SaeW, SaeX, SaeY, and SaeZ that are output from the protection units 42u, 42v, 42w, 42x, 42y, and 42z, respectively, the protection unit 42db does not execute the second protection operation. Thus, even when at least one of the protection units 42u, 42v, 42w, 42x, 42y, and 42z and the IGBTs 31u, 31v, 31w, 31x, 31y, and 31z is operating in an abnormal state, the semiconductor module 1 is capable of causing the brake unit 4db to cause the IGBT 31db to operate and continuing regenerative operation. By this configuration, even when at least one of the protection units 42u, 42v, 42w, 42x, 42y, and 42z and the IGBTs 31u, 31v, 31w, 31x, 31y, and 31z is operating in an abnormal state, the semiconductor module 1 is capable of preventing voltage that is input to the IGBTs 31u, 31v, 31w, 31x, 31y, and 31z (i.e., a potential difference between potential applied to the positive electrode-side power input terminal Tp and potential applied to the negative electrode-side power input terminal Tn) from becoming higher than the rated voltage.

As illustrated in FIG. 1, the semiconductor module 1 includes an alarm signal output terminal Talu that is connected to the control device 21 and a resistance element 11u that is disposed between the alarm signal output terminal Talu and the protection unit 42u. The semiconductor module 1 includes an alarm signal output terminal Talv that is connected to the control device 21 and a resistance element 11v that is disposed between the alarm signal output terminal Talv and the protection unit 42v. The semiconductor module 1 includes an alarm signal output terminal Talw that is connected to the control device 21 and a resistance element 11w that is disposed between the alarm signal output terminal Talw and the protection unit 42w. The semiconductor module 1 includes an alarm signal output terminal Talm that is connected to the control device 21 and a resistance element 11m that is disposed between the alarm signal output terminal Talm and the protection units 42x, 42y, 42z, and 42db.

Although details will be described later, when the protection unit 42u executes the first protection operation, the protection unit 42u outputs an alarm signal Salu to the control device 21 via the resistance element 11u and the alarm signal output terminal Talu. When the protection unit 42v executes the first protection operation, the protection unit 42v outputs an alarm signal Salv to the control device 21 via the resistance element 11v and the alarm signal output terminal Talv. When the protection unit 42w executes the first protection operation, the protection unit 42w outputs an alarm signal Salw to the control device 21 via the resistance element 11w and the alarm signal output terminal Talw.

Terminals to which the protection units 42x, 42y, 42z, and 42db output alarm signals are interconnected inside the semiconductor module 1. Thus, when at least one of the protection units 42x, 42y, and 42z executes the first protection operation or when the protection unit 42db executes the second protection operation, an alarm signal Salm is input to the control device 21 via the resistance element 11m and the alarm signal output terminal Talm.

When the alarm signal Salu, Salv, Salw, or Salm is input to the control device 21 from the semiconductor module 1, the control device 21 notifies a user of the semiconductor module 1 of occurrence of an abnormal state by a means such as light emission. By this configuration, the power conversion device including the semiconductor module 1 and the control device 21 is capable of notifying that the semiconductor module 1 is operating in an abnormal state.

### (Configuration of Gate Drive Unit and Brake Unit)

Next, schematic configurations of the gate drive units 4u, 4v, 4w, 4x, 4y, and 4z and the brake unit 4db that are included in the semiconductor module 1 according to the present embodiment will be described using FIG. 2 while referring to FIG. 1. The gate drive units 4u, 4v, 4w, 4x, 4y, and 4z have the same configuration as one another. Thus, hereinafter, the schematic configurations of the gate drive units 4u, 4v, 4w, 4x, 4y, and 4z will be described using the gate drive unit 4z as an example. FIG. 2 is a circuit diagram illustrative of an example of the schematic configurations of the gate drive unit 4z and the brake unit 4db. In FIG. 2, to facilitate understanding, the semiconductor element 3z that includes the IGBT 31z serving as a drive target of the gate drive unit 4z, the semiconductor element 3db that includes the IGBT 31db serving as a drive target of the brake unit 4db, the freewheeling diode 32db, and the constant voltage source 25 are also illustrated.

As illustrated in FIG. 2, the protection unit 42z disposed in the gate drive unit 4z includes an abnormality detection unit 422-1 (an example of a first abnormality detection unit) configured to detect whether or not at least one of the IGBT 31z and the pre-driver 41z is operating in an abnormal state. The protection unit 42z includes a protection signal generation unit 423-1 (an example of a first protection signal generation unit) configured to generate the protection signal SaeZ (an example of the first protection signal), based on a detection result by the abnormality detection unit 422-1. The protection unit 42z includes a determination unit 421-1 (an example of a first determination unit) configured to determine whether or not the second protection operation is executed, using the protection signal SaeDB (an example of the second protection signal) detected by the signal detection terminal Taez (an example of the first signal detection terminal). The determination unit 421-1 is also configured to determine whether or not the first protection operation is executed in the protection unit 42u, 42v, 42w, 42x, or 42y, using the protection signal SaeU, SaeV, SaeW, SaeX, or SaeY that is detected by the signal detection terminal Taez, respectively.

As illustrated in FIG. 2, the abnormality detection unit 422-1 includes a current detection unit 422c-1 configured to detect the detected current Isz that is output from the current detection element S disposed in the IGBT 31z as detected voltage Vsz. The current detection unit 422c-1 is formed by, for example, a resistance element. One terminal of the current detection unit 422c-1 is connected to a current output terminal of the current detection element S disposed in the IGBT 31z. The other terminal of the current detection unit 422c-1 is connected to the reference potential terminal Tgd. The current detection unit 422c-1 detects a voltage drop that occurs by the detected current Isz flowing through the current detection unit 422c-1 as the detected voltage Vsz. As described above, the current detection unit 422c-1 is capable of detecting the detected current Isz as the detected voltage Vsz.

The abnormality detection unit 422-1 includes a comparator 422a-1 that is connected to the current detection element S disposed in the IGBT 31z and the current detection unit 422c-1 and a comparison voltage generation unit 422b-1 configured to generate comparison voltage Vz1. The comparator 422a-1 is formed by, for example, an operational amplifier. The comparison voltage generation unit 422b-1 is formed by, for example, a DC power source. A non-inverting input terminal (+) of the comparator 422a-1 is connected to one terminal of the current detection unit 422c-1 and the current output terminal of the current detection element S disposed in the IGBT 31z. An inverting input terminal (−) of the comparator 422a-1 is connected to a positive electrode-side terminal of the comparison voltage generation unit 422b-1. An output terminal of the comparator 422a-1 is connected to one of three input terminals of a logical sum gate (OR gate) 422f-1 (details will be described later). A negative electrode-side terminal of the comparison voltage generation unit 422b-1 is connected to the reference potential terminal Tgd.

The comparison voltage Vz1 is set to, for example, a detected voltage Vsz to which a detected current Isz corresponding to a maximum current that can be flowed through the IGBT 31z (i.e., an absolute maximum rated current of collector-emitter current) is converted. Thus, when the detected voltage Vsz input from the current detection unit 422c-1 is lower than the comparison voltage Vz1 (i.e., when the IGBT 31z is operating in a normal state), the comparator 422a-1 outputs a comparison signal Sc1-1 having the low signal level to the OR gate 422f-1. In contrast, when the detected voltage Vsz input from the current detection unit 422c-1 is higher than the comparison voltage Vz1 (i.e., when the IGBT 31z is operating in an abnormal state), the comparator 422a-1 outputs the comparison signal Sc1-1 having the high signal level to the OR gate 422f-1.

As illustrated in FIG. 2, the abnormality detection unit 422-1 includes a comparator 422d-1 that is connected to the temperature detection element 33z disposed in the semiconductor element 3z and a comparison voltage generation unit 422e-1 configured to generate comparison voltage Vz2. The comparator 422d-1 is formed by, for example, an operational amplifier. The comparison voltage generation unit 422e-1 is formed by, for example, a DC power source. An inverting input terminal (−) of the comparator 422d-1 is connected to the anode of the diode by which the temperature detection element 33z is formed. A non-inverting input terminal (+) of the comparator 422d-1 is connected to a positive electrode-side terminal of the comparison voltage generation unit 422e-1. An output terminal of the comparator 422d-1 is connected to one of the three input terminals of the OR gate 422f-1. A negative electrode-side terminal of the comparison voltage generation unit 422e-1 is connected to the reference potential terminal Tgd.

By the way, the diode by which the temperature detection element 33z is formed is formed of silicon. The forward voltage of a diode formed of silicon is generally lower in the case where ambient temperature is high than in the case where the ambient temperature is low. The protection unit 42z includes a constant current source (not illustrated) that is connected to the anode of the temperature detection element 33z. Thus, when temperature of the IGBT 31z rises in the case where constant current is input from the constant current source to the temperature detection element 33z, a voltage drop in the temperature detection element 33z becomes small. As a result, the detected voltage Vtz detected by the temperature detection element 33z decreases as the temperature of the IGBT 31z becomes higher. Therefore, the comparator 422d-1 is capable of, by using the detected voltage Vtz that is input from the temperature detection element 33z and changes according to the temperature of the IGBT 31z, detecting whether or not the IGBT 31z is operating at an abnormal temperature exceeding an absolute maximum rated temperature.

The comparison voltage Vz2 is set to a detected voltage Vtz that corresponds to a maximum temperature at which the IGBT 31z can operate (i.e., the absolute maximum rated temperature). Thus, when the detected voltage Vtz input from the temperature detection element 33z is higher than the comparison voltage Vz2 (i.e., when the IGBT 31z is operating at a normal temperature), the comparator 422d-1 outputs a comparison signal Sc2-1 having the low signal level to the OR gate 422f-1. In contrast, when the detected voltage Vtz input from the temperature detection element 33z is lower than the comparison voltage Vz2 (i.e., when the IGBT 31z is operating at an abnormal temperature), the comparator 422d-1 outputs the comparison signal Sc2-1 having the high signal level to the OR gate 422f-1.

As illustrated in FIG. 2, the abnormality detection unit 422-1 includes the comparator 422g-1 that is connected to the power input terminal Tvc and a comparison voltage generation unit 422h-1 configured to generate comparison voltage Vz3. The comparator 422g-1 is formed by, for example, an operational amplifier. The comparison voltage generation unit 422h-1 is formed by, for example, a DC power source. An inverting input terminal (−) of the comparator 422g-1 is connected to the power input terminal Tvc. A non-inverting input terminal (+) of the comparator 422g-1 is connected to a positive electrode-side terminal of the comparison voltage generation unit 422h-1. An output terminal of the comparator 422g-1 is connected to one of the three input terminals of the OR gate 422f-1. A negative electrode-side terminal of the comparison voltage generation unit 422h-1 is connected to the reference potential terminal Tgd.

The comparison voltage Vz3 is set to a voltage higher than a minimum voltage at which the pre-driver 41z can operate (i.e., an absolute minimum rated voltage). Thus, when the power supply voltage VDD that is generated by the constant voltage source 25 and is input to the power input terminal Tvc is higher than the comparison voltage Vz3 (i.e., when the pre-driver 41z is operating at a normal power supply voltage), the comparator 422g-1 outputs a comparison signal Sc3-1 having the low signal level to the OR gate 422f-1. In contrast, when the power supply voltage VDD that is generated by the constant voltage source 25 and is input to the power input terminal Tvc is lower than the comparison voltage Vz3 (i.e., when the pre-driver 41z is operating at an abnormal power supply voltage), the comparator 422g-1 outputs the comparison signal Sc3-1 having the high signal level to the OR gate 422f-1.

As illustrated in FIG. 2, the abnormality detection unit 422-1 includes the OR gate 422f-1 that is connected to the comparators 422a-1, 422d-1, and 422g-1. The OR gate 422f-1 has a configuration of three inputs and one output. To one of the three input terminals of the OR gate 422f-1, the output terminal of the comparator 422a-1 is connected. To one of the remaining input terminals of the OR gate 422f-1, the output terminal of the comparator 422d-1 is connected. To the remaining input terminal of the OR gate 422f-1, the output terminal of the comparator 422g-1 is connected. Thus, to the OR gate 422f-1, the comparison signals Sc1-1, Sc2-1, and Sc3-1 that are output from the comparators 422a-1, 422d-1, and 422g-1, respectively, are input.

The OR gate 422f-1 outputs an operation signal Sca-1 that is obtained by performing a logical operation on the signal levels of the comparison signals Sc1-1, Sc2-1, and Sc3-1 input to the OR gate 422f-1 to the protection signal generation unit 423-1. The OR gate 422f-1 outputs the operation signal Sca-1 having the low signal level to the protection signal generation unit 423-1 when all the signal levels of the comparison signals Sc1-1, Sc2-1, and Sc3-1 are the low level (i.e., when neither the IGBT 31z nor the pre-driver 41z is operating in an abnormal state). In contrast, the OR gate 422f-1 outputs the operation signal Sca-1 having the high signal level to the protection signal generation unit 423-1 when at least one of the signal levels of the comparison signals Sc1-1, Sc2-1, and Sc3-1 is the high level (i.e., when at least one of the IGBT 31z and the pre-driver 41z is operating in an abnormal state).

As illustrated in FIG. 2, the protection signal generation unit 423-1 includes a delay flip-flop (DFF) 423a-1 that is connected to the OR gate 422f-1 and a transistor 423b-1 that is connected to the DFF 423a-1. The transistor 423b-1 is formed by, for example, an N-type MOS transistor. To a signal input terminal (D) of the DFF 423a-1, an output terminal of the OR gate 422f-1 is connected. An output terminal (Q) of the DFF 423a-1 is connected to a gate of the transistor 423b-1. To a clock signal input terminal (C) of the DFF 423a-1, a clock signal CK-1 is input. The clock signal CK-1 may be input from the control device 21 (see FIG. 1), or the semiconductor module 1 may include an oscillator configured to generate the clock signal CK-1.

Thus, when the clock signal CK-1 rises in the case where the signal level of the operation signal Sca-1, which is input from the OR gate 422f-1, is the high level, the DFF 423a-1 outputs an output signal having the high signal level from the output terminal (Q) to the gate of the transistor 423b-1. In contrast, when the clock signal CK-1 rises in the case where the signal level of the operation signal Sca-1, which is input from the OR gate 422f-1, is the low level, the DFF 423a-1 outputs an output signal having the low signal level from the output terminal (Q) to the gate of the transistor 423b-1.

The protection unit 42z includes a constant current source 424-1 that operates using the power input terminal Tvc as a power source. A drain of the transistor 423b-1 is connected to an output terminal of the constant current source 424-1. A source of the transistor 423b-1 is connected to the reference potential terminal Tgd. The gate of the transistor 423b-1 is connected to the output terminal (Q) of the DFF 423a-1. In addition, the drain of the transistor 423b-1 and the output terminal of the constant current source 424-1 are connected to the signal detection terminal Taez.

Thus, since the transistor 423b-1 disconnects the signal detection terminal Taez and the reference potential terminal Tgd from each other when the transistor 423b-1 is in an OFF state, the transistor 423b-1 sets a voltage level of the signal detection terminal Taez to the high level. In this case, since the protection signal generation unit 423-1 does not output the protection signal SaeZ to the signal detection terminal Taez, the signal detection terminals Taeu, Taev, Taew, Taex, and Taey (see FIG. 1) and the signal detection terminal Taedb do not detect the protection signal SaeZ. In contrast, since the transistor 423b-1 connects the signal detection terminal Taez and the reference potential terminal Tgd to each other when the transistor 423b-1 is in an ON state, the transistor 423b-1 sets the voltage level of the signal detection terminal Taez to the low level. By this configuration, the protection signal generation unit 423-1 outputs the protection signal SaeZ having the low signal level to the signal detection terminal Taez, and the signal detection terminals Taeu, Taev, Taew, Taex, Taey, and Taedb thus detect the protection signal SaeZ.

As described above, when neither the IGBT 31z nor the pre-driver 41z is operating in an abnormal state, the abnormality detection unit 422-1 outputs the operation signal Sca-1 having the low signal level from the OR gate 422f-1 to the signal input terminal (D) of the DFF 423a-1. By this configuration, the DFF 423a-1, caused by a rise of the clock signal CK-1, outputs an output signal having the low signal level to the gate of the transistor 423b-1, and the transistor 423b-1 thus switches to the OFF state. Thus, when neither the IGBT 31z nor the pre-driver 41z is operating in an abnormal state, the protection signal generation unit 423-1 does not output the protection signal SaeZ to the signal detection terminal Taez.

In contrast, when at least one of the IGBT 31z and the pre-driver 41z is operating in an abnormal state, the abnormality detection unit 422-1 outputs the operation signal Sca-1 having the high signal level from the OR gate 422f-1 to the signal input terminal (D) of the DFF 423a-1. By this configuration, the DFF 423a-1, caused by a rise of the clock signal CK-1, outputs an output signal having the high signal level to the gate of the transistor 423b-1, and the transistor 423b-1 thus switches to the ON state. Thus, when at least one of the IGBT 31z and the pre-driver 41z is operating in an abnormal state, the protection signal generation unit 423-1 outputs the protection signal SaeZ to the signal detection terminal Taez.

As illustrated in FIG. 2, the resistance element 11m is disposed in the semiconductor module 1 with one terminal connected to the alarm signal output terminal Talm and the other terminal connected to the output terminal of the constant current source 424-1 and the drain of the transistor 423b-1. Thus, the alarm signal output terminal Talm is connected to the signal detection terminal Taez via the resistance element 11m. When neither the IGBT 31z nor the pre-driver 41z is operating in an abnormal state, the alarm signal output terminal Talm maintains the voltage level at the high level and does not output the alarm signal Salm to the control device 21 (see FIG. 1). In contrast, when at least one of the IGBT 31z and the pre-driver 41z is operating in an abnormal state, the alarm signal output terminal Talm outputs the alarm signal Salm having the low signal level to the control device 21.

As illustrated in FIG. 2, the determination unit 421-1 includes a comparator 421a-1 that is connected to the signal detection terminal Taez and a comparison voltage generation unit 421b-1 configured to generate comparison voltage Vz4. The comparator 421a-1 is formed by, for example, an operational amplifier. The comparison voltage generation unit 421b-1 is formed by, for example, a DC power source. An inverting input terminal (−) of the comparator 421a-1 is connected to the signal detection terminal Taez. A non-inverting input terminal (+) of the comparator 421a-1 is connected to a positive electrode-side terminal of the comparison voltage generation unit 421b-1. An output terminal of the comparator 421a-1 is connected to the pre-driver 41z. A negative electrode-side terminal of the comparison voltage generation unit 421b-1 is connected to the reference potential terminal Tgd.

The comparison voltage Vz4 is, for example, set to a voltage higher than the voltage level of the protection signals SaeU, SaeV, SaeW, SaeX, SaeY, and SaeDB that are detected by the signal detection terminal Taez (for example, an intermediate voltage of a potential difference between a potential of voltage that the constant voltage source 25 generates and a potential at the reference potential terminal Tgd). Thus, when none of the protection signals SaeU, SaeV, SaeW, SaeX, SaeY, and SaeDB is detected by the signal detection terminal Taez, the comparator 421a-1 outputs a continuation signal Scnz having the low signal level to the pre-driver 41z. In contrast, when any one of the protection signals SaeU, SaeV, SaeW, SaeX, SaeY, and SaeDB is detected by the signal detection terminal Taez, the comparator 421a-1 outputs a suspension signal Sspz having the high signal level to the pre-driver 41z.

Although detailed description is omitted, when the continuation signal Scnz is input from the determination unit 421-1, the pre-driver 41z generates the gate drive signal SgZ according to a signal level of the input signal InZ that is input from the signal input terminal TinZ. In contrast, when the suspension signal Sspz is input from the determination unit 421-1, the pre-driver 41z generates the gate drive signal SgZ having a signal level that causes the IGBT 31z to switch to the OFF state regardless of the signal level of the input signal InZ that is input from the signal input terminal TinZ.

Thus, when the signal detection terminal Taez does not detect any of the protection signals SaeU, SaeV, SaeW, SaeX, SaeY, and SaeDB (i.e., when the continuation signal Scnz having the low signal level is input from the determination unit 421-1), the pre-driver 41z outputs the gate drive signal SgZ matching the signal level of the input signal InZ that is input from the signal input terminal TinZ to the gate G of the IGBT 31z. By this configuration, when the signal detection terminal Taez does not detect any of the protection signals SaeU, SaeV, SaeW, SaeX, SaeY, and SaeDB (i.e., when none of the IGBTs 31u, 31v, 31w, 31x, 31y, and 31db and the pre-drivers 41u, 41v, 41w, 41x, 41y, and 41db is operating in an abnormal state), the IGBT 31z operates based on control by the control device 21.

In contrast, when the signal detection terminal Taez detects at least one of the protection signals SaeU, SaeV, SaeW, SaeX, SaeY, and SaeDB (i.e., when the suspension signal Sspz is input from the determination unit 421-1), the pre-driver 41z outputs the gate drive signal SgZ for causing the IGBT 31z to switch to the OFF state to the gate G of the IGBT 31z. By this configuration, when the signal detection terminal Taez detects at least one of the protection signals SaeU, SaeV, SaeW, SaeX, SaeY, and SaeDB (i.e., when at least one of the IGBTs 31u, 31v, 31w, 31x, 31y, and 31db and the pre-drivers 41u, 41v, 41w, 41x, 41y, and 41db is operating in an abnormal state), the IGBT 31z switches to the OFF state independently of the control by the control device 21.

As described above, when at least one of the IGBT 31z and the pre-driver 41z is operating in an abnormal state, the abnormality detection unit 422-1 outputs the operation signal Sca-1 having the high signal level to the DFF 423a-1 of the protection signal generation unit 423-1. Thus, when at least one of the IGBT 31z and the pre-driver 41z is operating in an abnormal state, the protection signal generation unit 423-1 brings a voltage level of the inverting input terminal (−) of the comparator 421a-1 disposed in the determination unit 421-1 to the low level. Thus, when the abnormality detection unit 422-1 detects that at least one of the IGBT 31z and the pre-driver 41z is operating in an abnormal state, the comparator 421a-1 disposed in the determination unit 421-1 also outputs the suspension signal Sspz having the high signal level to the pre-driver 41z. By this configuration, when at least one of the IGBT 31z and the pre-driver 41z is operating in an abnormal state, the pre-driver 41z also drives the IGBT 31z to the OFF state independently of the control by the control device 21.

Next, a configuration of the brake unit 4db will be described.

As illustrated in FIG. 2, the protection unit 42db disposed in the brake unit 4db includes an abnormality detection unit 422-2 (an example of a second abnormality detection unit) configured to detect whether or not the IGBT 31db is operating in an abnormal state. The protection unit 42db includes a protection signal generation unit 423-2 (an example of a second protection signal generation unit) configured to generate the protection signal SaeDB (an example of the second protection signal), based on a detection result by the abnormality detection unit 422-2. The protection unit 42db includes a determination unit 421-2 (an example of a second determination unit) configured to determine whether or not the first protection operation is executed, using the protection signals SaeU, SaeV, SaeW, SaeX, SaeY, and SaeZ (examples of the first protection signal) detected by the signal detection terminal Taedb (an example of the second signal detection terminal).

As illustrated in FIG. 2, the abnormality detection unit 422-2 includes a current detection unit 422c-2 configured to detect the detected current Isdb output from the current detection element S disposed in the IGBT 31db as detected voltage Vsdb. The current detection unit 422c-2 is formed by, for example, a resistance element. One terminal of the current detection unit 422c-2 is connected to a current output terminal of the current detection element S disposed in the IGBT 31db. The other terminal of the current detection unit 422c-2 is connected to the reference potential terminal Tgd. The current detection unit 422c-2 detects a voltage drop that occurs by the detected current Isdb flowing through the current detection unit 422c-2 as the detected voltage Vsdb. As described above, the current detection unit 422c-2 is capable of detecting the detected current Isdb as the detected voltage Vsdb.

The abnormality detection unit 422-2 includes a comparator 422a-2 that is connected to the current detection element S disposed in the IGBT 31db and the current detection unit 422c-2 and a comparison voltage generation unit 422b-2 configured to generate comparison voltage Vdb1. The comparator 422a-2 is formed by, for example, an operational amplifier. The comparison voltage generation unit 422b-2 is formed by, for example, a DC power source. A non-inverting input terminal (+) of the comparator 422a-2 is connected to one terminal of the current detection unit 422c-2 and the current output terminal of the current detection element S disposed in the IGBT 31db. An inverting input terminal (−) of the comparator 422a-2 is connected to a positive electrode-side terminal of the comparison voltage generation unit 422b-2. An output terminal of the comparator 422a-2 is connected to one of three input terminals of a logical sum gate (OR gate) 422f-2 (details will be described later). A negative electrode-side terminal of the comparison voltage generation unit 422b-2 is connected to the reference potential terminal Tgd.

The comparison voltage Vdb1 is set to, for example, a detected voltage Vsdb to which a detected current Isdb that corresponds to a maximum current that can be flowed through the IGBT 31db (i.e., an absolute maximum rated current of collector-emitter current) is converted. Thus, when the detected voltage Vsdb input from the current detection unit 422c-2 is lower than the comparison voltage Vdb1 (i.e., when the IGBT 31db is operating in a normal state), the comparator 422a-2 outputs a comparison signal Sc1-2 having the low signal level to the OR gate 422f-2. In contrast, when the detected voltage Vsdb input from the current detection unit 422c-2 is higher than the comparison voltage Vdb1 (i.e., when the IGBT 31db is operating in an abnormal state), the comparator 422a-2 outputs the comparison signal Sc1-2 having the high signal level to the OR gate 422f-2.

As illustrated in FIG. 2, the abnormality detection unit 422-2 includes a comparator 422d-2 that is connected to the temperature detection element 33db disposed in the semiconductor element 3db and a comparison voltage generation unit 422e-2 configured to generate comparison voltage Vdb2. The comparator 422d-2 is formed by, for example, an operational amplifier. The comparison voltage generation unit 422e-2 is formed by, for example, a DC power source. An inverting input terminal (−) of the comparator 422d-2 is connected to the anode of the diode by which the temperature detection element 33db is formed. A non-inverting input terminal (+) of the comparator 422d-2 is connected to a positive electrode-side terminal of the comparison voltage generation unit 422e-2. An output terminal of the comparator 422d-2 is connected to one of the three input terminals of the OR gate 422f-2. A negative electrode-side terminal of the comparison voltage generation unit 422e-2 is connected to the reference potential terminal Tgd.

The protection unit 42db includes a constant current source (not illustrated) that is connected to the anode of the temperature detection element 33db. Thus, when temperature of the IGBT 31db rises in the case where constant current is input from the constant current source to the temperature detection element 33db, a voltage drop in the temperature detection element 33db becomes small. As a result, the detected voltage Vtdb detected by the temperature detection element 33db decreases as the temperature of the IGBT 31db becomes higher. Therefore, the comparator 422d-2 is capable of, by using the detected voltage Vtdb that is input from the temperature detection element 33db and changes according to the temperature of the IGBT 31db, detecting whether or not the IGBT 31db is operating at an abnormal temperature exceeding an absolute maximum rated temperature.

The comparison voltage Vdb2 is set to a detected voltage Vtdb that corresponds to a maximum temperature at which the IGBT 31db can operate (i.e., the absolute maximum rated temperature). Thus, when the detected voltage Vtdb input from the temperature detection element 33db is higher than the comparison voltage Vdb2 (i.e., when the IGBT 31db is operating at a normal temperature), the comparator 422d-2 outputs a comparison signal Sc2-2 having the low signal level to the OR gate 422f-2. In contrast, when the detected voltage Vtdb input from the temperature detection element 33db is lower than the comparison voltage Vdb2 (i.e., when the IGBT 31db is operating at an abnormal temperature), the comparator 422d-2 outputs the comparison signal Sc2-2 having the high signal level to the OR gate 422f-2.

As illustrated in FIG. 2, the semiconductor module 1 includes a detection unit 422gh that is disposed in the abnormality detection unit 422-2 and configured to detect whether or not the pre-driver 41db is operating in an abnormal state. The detection unit 422gh includes the comparator 422g-2 that is connected to the power input terminal Tvc and a comparison voltage generation unit 422h-2 configured to generate comparison voltage Vdb3. The comparator 422g-2 is formed by, for example, an operational amplifier. The comparison voltage generation unit 422h-2 is formed by, for example, a DC power source. An inverting input terminal (−) of the comparator 422g-2 is connected to the power input terminal Tvc. A non-inverting input terminal (+) of the comparator 422g-2 is connected to a positive electrode-side terminal of the comparison voltage generation unit 422h-2. An output terminal of the comparator 422g-2 is connected to one of the three input terminals of the OR gate 422f-2. A negative electrode-side terminal of the comparison voltage generation unit 422h-2 is connected to the reference potential terminal Tgd.

The comparison voltage Vdb3 is, for example, set to a minimum power supply voltage at which the pre-driver 41db can operate (i.e., an absolute minimum rated voltage). The comparison voltage Vdb3 is set to a voltage lower than the comparison voltage Vz3. Thus, when the power supply voltage VDD that is generated by the constant voltage source 25 and is input to the power input terminal Tvc is higher than the comparison voltage Vdb3 (i.e., when the pre-driver 41db is operating at a normal power supply voltage), the comparator 422g-2 outputs a comparison signal Sc3-2 having the low signal level to the OR gate 422f-2. In contrast, when the power supply voltage VDD that is generated by the constant voltage source 25 and is input to the power input terminal Tvc is lower than the comparison voltage Vdb3 (i.e., when the pre-driver 41db is operating at an abnormal power supply voltage), the comparator 422g-2 outputs the comparison signal Sc3-2 having the high signal level to the OR gate 422f-2.

As illustrated in FIG. 2, the abnormality detection unit 422-2 includes the OR gate 422f-2 that is connected to the comparators 422a-2, 422d-2, and 422g-2. The OR gate 422f-2 has a configuration of three inputs and one output. To one of the three input terminals of the OR gate 422f-2, the output terminal of the comparator 422a-2 is connected. To one of the remaining input terminals of the OR gate 422f-2, the output terminal of the comparator 422d-2 is connected. To the remaining input terminal of the OR gate 422f-2, the output terminal of the comparator 422g-2 is connected. Thus, to the OR gate 422f-2, the comparison signals Sc1-2, Sc2-2, and Sc3-2 that are output from the comparators 422a-2, 422d-2, and 422g-2, respectively, are input.

The OR gate 422f-2 outputs an operation signal Sca-2 that is obtained by performing a logical operation on the signal levels of the comparison signals Sc1-2, Sc2-2, and Sc3-2 input to the OR gate 422f-1 to the protection signal generation unit 423-2. The OR gate 422f-2 outputs the operation signal Sca-2 having the low signal level to the protection signal generation unit 423-2 when all the signal levels of the comparison signals Sc1-2, Sc2-2, and Sc3-2 are the low level (i.e., when neither the IGBT 31db nor the pre-driver 41db is operating in an abnormal state). In contrast, the OR gate 422f-2 outputs the operation signal Sca-2 having the high signal level to the protection signal generation unit 423-2 when at least one of the signal levels of the comparison signals Sc1-2, Sc2-2, and Sc3-2 is the high level (i.e., when at least one of the IGBT 31db and the pre-driver 41db is operating in an abnormal state).

As illustrated in FIG. 2, the protection signal generation unit 423-2 includes a delay flip-flop (DFF) 423a-2 that is connected to the OR gate 422f-2 and a transistor 423b-2 that is connected to the DFF 423a-2. The transistor 423b-2 is formed by, for example, an N-type MOS transistor. To a signal input terminal (D) of the DFF 423a-2, an output terminal of the OR gate 422f-2 is connected. An output terminal (Q) of the DFF 423a-2 is connected to a gate of the transistor 423b-2. To a clock signal input terminal (C) of the DFF 423a-2, a clock signal CK-2 is input. The clock signal CK-2 may be input from the control device 21 (see FIG. 1), or the semiconductor module 1 may include an oscillator that generates the clock signal CK-2.

Thus, when the clock signal CK-2 rises in the case where the signal level of the operation signal Sca-2, which is input from the OR gate 422f-2, is the high level, the DFF 423a-2 outputs an output signal having the high signal level from the output terminal (Q) to the gate of the transistor 423b-2. In contrast, when the clock signal CK-2 rises in the case where the signal level of the operation signal Sca-2, which is input from the OR gate 422f-2, is the low level, the DFF 423a-2 outputs an output signal having the low signal level from the output terminal (Q) to the gate of the transistor 423b-2.

The protection unit 42db includes a constant current source 424-2 that operates using the power input terminal Tvc as a power source. A drain of the transistor 423b-2 is connected to an output terminal of the constant current source 424-2. A source of the transistor 423b-2 is connected to the reference potential terminal Tgd. The gate of the transistor 423b-2 is connected to the output terminal (Q) of the DFF 423a-2. In addition, the drain of the transistor 423b-2 and the output terminal of the constant current source 424-2 are connected to the signal detection terminal Taedb.

Thus, since the transistor 423b-2 disconnects the signal detection terminal Taedb and the reference potential terminal Tgd from each other when the transistor 423b-2 is in an OFF state, the transistor 423b-2 sets a voltage level of the signal detection terminal Taedb to the high level. In this case, since the protection signal generation unit 423-2 does not output the protection signal SaeDB to the signal detection terminal Taedb, the signal detection terminals Taeu, Taev, Taew, Taex, Taey, and Taez do not detect the protection signal SaeDB. In contrast, since the transistor 423b-2 connects the signal detection terminal Taedb and the reference potential terminal Tgd to each other when the transistor 423b-2 is in an ON state, the transistor 423b-2 sets the voltage level of the signal detection terminal Taedb to the low level. By this configuration, the protection signal generation unit 423-2 outputs the protection signal SaeDB having the low signal level to the signal detection terminal Taedb, and the signal detection terminals Taeu, Taev, Taew, Taex, Taey, and Taez thus detect the protection signal SaeDB.

As described above, when neither the IGBT 31db nor the pre-driver 41db is operating in an abnormal state, the abnormality detection unit 422-2 outputs the operation signal Sca-2 having the low signal level from the OR gate 422f-2 to the signal input terminal (D) of the DFF 423a-2. By this configuration, the DFF 423a-2, caused by a rise of the clock signal CK-2, outputs an output signal having the low signal level to the gate of the transistor 423b-2, and the transistor 423b-2 thus switches to the OFF state. Thus, when neither the IGBT 31db nor the pre-driver 41db is operating in an abnormal state, the protection signal generation unit 423-2 does not output the protection signal SaeDB to the signal detection terminal Taedb.

In contrast, when at least one of the IGBT 31db and the pre-driver 41db is operating in an abnormal state, the abnormality detection unit 422-2 outputs the operation signal Sca-2 having the high signal level from the OR gate 422f-2 to the signal input terminal (D) of the DFF 423a-2. By this configuration, the DFF 423a-2, caused by a rise of the clock signal CK-2, outputs an output signal having the high signal level to the gate of the transistor 423b-2, and the transistor 423b-2 thus switches to the ON state. Thus, when at least one of the IGBT 31db and the pre-driver 41db is operating in an abnormal state, the protection signal generation unit 423-2 outputs the protection signal SaeDB to the signal detection terminal Taedb.

As illustrated in FIG. 2, the other terminal of the resistance element 11m is connected to the output terminal of the constant current source 424-2 and the drain of the transistor 423b-2. Thus, the alarm signal output terminal Talm is connected to the signal detection terminal Taedb via the resistance element 11m. When neither the IGBT 31db nor the pre-driver 41db is operating in an abnormal state, the alarm signal output terminal Talm maintains the voltage level at the high level and does not output the alarm signal Salm to the control device 21. In contrast, when at least one of the IGBT 31db and the pre-driver 41db is operating in an abnormal state, the alarm signal output terminal Talm outputs the alarm signal Salm having the low signal level to the control device 21.

As illustrated in FIG. 2, the determination unit 421-2 includes a comparator 421a-2 that is connected to the signal detection terminal Taedb and a comparison voltage generation unit 421b-2 configured to generate comparison voltage Vdb4. The comparator 421a-2 is formed by, for example, an operational amplifier. The comparison voltage generation unit 421b-2 is formed by, for example, a DC power source. An inverting input terminal (−) of the comparator 421a-2 is connected to the signal detection terminal Taedb. A non-inverting input terminal (+) of the comparator 421a-2 is connected to a positive electrode-side terminal of the comparison voltage generation unit 421b-2. An output terminal of the comparator 421a-2 is connected to a continuation signal generation unit 425-2. A negative electrode-side terminal of the comparison voltage generation unit 421b-2 is connected to the reference potential terminal Tgd.

The comparison voltage Vdb4 is, for example, set to a voltage higher than the voltage level of the protection signals SaeU, SaeV, SaeW, SaeX, SaeY, and SaeZ that are detected by the signal detection terminal Taedb (for example, an intermediate voltage of a potential difference between the potential of the voltage that the constant voltage source 25 generates and the potential at the reference potential terminal Tgd). Thus, when none of the protection signals SaeU, SaeV, SaeW, SaeX, SaeY, and SaeZ is detected by the signal detection terminal Taedb, the comparator 421a-2 outputs a comparison signal Sc4-2 having the low signal level to the continuation signal generation unit 425-2 (detailed will be described later). In contrast, when any one of the protection signals SaeU, SaeV, SaeW, SaeX, SaeY, and SaeZ is detected by the signal detection terminal Taedb, the comparator 421a-2 outputs the comparison signal Sc4-2 having the high signal level to the continuation signal generation unit 425-2.

As illustrated in FIG. 2, the semiconductor module 1 includes the continuation signal generation unit 425-2 configured to generate a continuation signal Scndb for causing the IGBT 31db to continue to operate, based on a detection result by the abnormality detection unit 422-2, a detection result by the detection unit 422gh, and a determination result by the determination unit 421-2 and output the generated continuation signal Scndb to the pre-driver 41db. The continuation signal generation unit 425-2 is disposed in the protection unit 42db.

The continuation signal generation unit 425-2 includes a negative logical product gate (NAND gate) 425a-2 that is connected to the detection unit 422gh and the determination unit 421-2, a logical product gate (AND gate) 425b-2 that is connected to the detection unit 422gh and the NAND gate 425a-2, and a logical sum gate (OR gate) 425c-2 that is connected to the AND gate 425b-2 and the OR gate 422f-2. The NAND gate 425a-2, the AND gate 425b-2, and the OR gate 425c-2 have a configuration of two inputs and one output.

To one input terminal of the NAND gate 425a-2, the output terminal of the comparator 422g-2, which is disposed in the detection unit 422gh, is connected. To the other input terminal of the NAND gate 425a-2, the output terminal of the comparator 421a-2, which is disposed in the determination unit 421-2, is connected. An output terminal of the NAND gate 425a-2 is connected to one input terminal of the AND gate 425b-2. To the other input terminal of the AND gate 425b-2, the output terminal of the comparator 422g-2 is connected. To one input terminal of the OR gate 425c-2, an output terminal of the AND gate 425b-2 is connected. To the other input terminal of the OR gate 425c-2, the output terminal of the OR gate 422f-2 is connected.

By this configuration, the NAND gate 425a-2 outputs an operation signal Scaa that is obtained by performing a negative logical product operation on the comparison signal Sc3-2 input from the comparator 422g-2 and the comparison signal Sc4-2 input from the comparator 421a-2 to the AND gate 425b-2. The AND gate 425b-2 outputs an operation signal Scab that is obtained by performing a logical product operation on the operation signal Scaa input from the NAND gate 425a-2 and the comparison signal Sc3-2 input from the comparator 422g-2 to the OR gate 425c-2. The OR gate 425c-2 outputs an operation signal that is obtained by performing a logical sum operation on the operation signal Scab input from the AND gate 425b-2 and the operation signal Sca-2 input from the OR gate 422f-2 to the pre-driver 41db as the continuation signal Scndb.

As described above, the continuation signal generation unit 425-2 generates the continuation signal Scndb that is obtained by performing logical operations on the operation signal Sca-2 serving as a detection result by the abnormality detection unit 422-2, the comparison signal Sc3-2 serving as a detection result by the detection unit 422gh, and the comparison signal Sc4-2 serving as a determination result by the determination unit 421-2 and outputs the generated continuation signal Scndb to the pre-driver 41db.

Although detailed operation of the continuation signal generation unit 425-2 will be described later, the continuation signal generation unit 425-2 generates the continuation signal Scndb having the same signal level regardless of a detection result by the abnormality detection unit 422-1. In addition, the continuation signal generation unit 425-2 generates the continuation signal Scndb having the same signal level regardless of a detection result by an abnormality detection unit (not illustrated) that is disposed in each of the protection units 42u, 42v, 42w, 42x, and 42y. For example, the continuation signal generation unit 425-2 generates the continuation signal Scndb having the low signal level regardless of a detection result by an abnormality detection unit that is disposed in each of the protection units 42u, 42v, 42w, 42x, and 42y. When the signal level of the continuation signal Scndb is the low level, the pre-driver 41db outputs the brake drive signal SgDB matching the signal level of the input signal InDB that is input from the signal input terminal TinDB to the gate G of the IGBT 31db. By this configuration, the IGBT 31db operates based on control by the control device 21 regardless of whether or not the signal detection terminal Taedb detects at least one of the protection signals SaeU, SaeV, SaeW, SaeX, SaeY, and SaeZ (i.e., regardless of whether or not at least one of the IGBTs 31u, 31v, 31w, 31x, 31y, and 31z and the pre-drivers 41u, 41v, 41w, 41x, 41y, and 41z is operating in an abnormal state).

As a result, the brake unit 4db is capable of continuing operation even when at least one of the pre-drivers 41u, 41v, 41w, 41x, 41y, and 41z is operating in an abnormal state in which power supply voltage of the pre-driver is reduced. By this configuration, the IGBT 31db for braking can continue on/off operation, and the semiconductor module 1 is thus capable of preventing voltage that is input from the AC power unit 22 to the IGBTs 31u, 31v, 31w, 31x, 31y, and 31z from becoming higher than a rated voltage.

In addition, when the abnormality detection unit 422-2 detects an abnormality, the continuation signal generation unit 425-2 outputs a suspension signal Sspdb having the high signal level to the pre-driver 41db. When the suspension signal Sspdb is input from the continuation signal generation unit 425-2, the pre-driver 41db outputs the brake drive signal SgDB that causes the IGBT 31db to switch to the OFF state regardless of a signal level of the input signal InDB that is input from the signal input terminal TinDB to the gate G of the IGBT 31db. By this configuration, the IGBT 31db is driven to the OFF state independently of control by the control device 21. As a result, when at least one of the IGBT 31db and the pre-driver 41db is operating in an abnormal state, the semiconductor module 1 is capable of controlling the IGBT 31db to the OFF state and temporarily suspending operation of the IGBT 31db.

### (Operation of Semiconductor Module)

Operation of the semiconductor module 1 according to the present embodiment will be described using FIGS. 1 and 2. Hereinafter, the operation of the semiconductor module 1 will be described using operation of the brake unit 4db as an example.

Table 1 illustrates a relationship between operating states of an IGBT and a pre-driver and operation of the continuation signal generation unit. “VDD” in Table 1 denotes the constant voltage source 25. “Isdb” in Table 1 denotes the detected current Isdb that is output from the current detection element S disposed in the IGBT 31db. “Vtdb” in Table 1 denotes the detected voltages Vtdb that is detected by a current detection unit 422c-3 disposed in the protection unit 42db. “Taedb” in Table 1 denotes the signal detection terminal Taedb that is disposed to the semiconductor module 1.

“Sc4-2” in Table 1 denotes the comparison signal Sc4-2 that is output from the determination unit 421-2 disposed in the protection unit 42db. “Sc3-2” in Table 1 denotes the comparison signal Sc3-2 that is output from the detection unit 422gh disposed in the protection unit 42db. “Scaa” in Table 1 denotes the operation signal Scaa that is output from the NAND gate 425a-2 disposed in the continuation signal generation unit 425-2 of the protection unit 42db. “Scab” in Table 1 denotes the operation signal Scab that is output from the AND gate 425b-2 disposed in the continuation signal generation unit 425-2 of the protection unit 42db. “Sca-2” in Table 1 denotes the operation signal Sca-2 that is output from the abnormality detection unit 422-2 disposed in the protection unit 42db. “Scndb” in Table 1 denotes the continuation signal Scndb that is output from the continuation signal generation unit 425-2 of the protection unit 42db.

A circle mark in Table 1 indicates that the IGBT 31db or the pre-driver 41db is in a normal state. A cross mark in Table 1 indicates that the IGBT 31db or the pre-driver 41db is in an abnormal state. “H” in Table 1 indicates that the signal level is the high level. “L” in Table 1 indicates that the signal level is the low level. “-” in Table 1 indicates that no continuation signal is output (in other words, a suspension signal is output). Hereinafter, when Table 1 is referred to, a row number in the table will be specified excluding a row in which items, such as “VDD”, are described.

TABLE 1

| VDD | Isdb | Vtdb | Taedb | Sc4-2 | Sc3-2 | Scaa | Scab | Sca-2 | Scndb |
|---|---|---|---|---|---|---|---|---|---|
| ◯ | ◯ | ◯ | H | L | L | H | L | L | L |
| X | ◯ | ◯ | L | H | H | L | L | H | — |
| ◯ | X | ◯ | L | H | L | H | L | H | — |
| ◯ | ◯ | X | L | H | L | H | L | H | — |
| ◯ | ◯ | ◯ | L | H | L | H | L | L | L |

### (Normal Operation)

First, a normal operation in which none of the IGBTs 31u, 31v, 31w, 31x, 31y, 31z, and 31db and the pre-drivers 41u, 41v, 41w, 41x, 41y, 41z, and 41db, which are disposed in the semiconductor module 1, is operating in an abnormal state will be described.

When the semiconductor module 1 is normally operating, the voltage level of the signal detection terminal Taedb (see FIG. 2) becomes the high level since the signal detection terminal Taedb does not detect a protection signal, as illustrated in the first row in Table 1. As a result, the voltage at the signal detection terminal Taedb becomes higher than the comparison voltage Vdb4 (see FIG. 2) that is generated by the comparison voltage generation unit 421b-1 disposed in the determination unit 421-2. Thus, the determination unit 421-2 outputs the comparison signal Sc4-2 having the low signal level to the continuation signal generation unit 425-2 (see FIG. 2).

In addition, when the semiconductor module 1 is normally operating, the signal level of the comparison signal Sc3-2 (see FIG. 2) that is output from the detection unit 422gh disposed in the protection unit 42db becomes the low level, as illustrated in the first row in Table 1. Thus, as illustrated in the first row in Table 1, the signal level of the operation signal Scaa (see FIG. 2) that is output from the NAND gate 425a-2 disposed in the continuation signal generation unit 425-2 becomes the high level, and the signal level of the operation signal Scab that is output from the AND gate 425b-2 disposed in the continuation signal generation unit 425-2 becomes the low level.

In addition, when the semiconductor module 1 is normally operating, the signal level of the operation signal Sca-2 (see FIG. 2) that is output from the abnormality detection unit 422-2 disposed in the protection unit 42db becomes the low level, as illustrated in the first row in Table 1. Thus, the continuation signal generation unit 425-2 outputs the continuation signal Scndb having the low signal level to the pre-driver 41db. Through this processing, the pre-driver 41db generates the brake drive signal SgDB for causing the IGBT 31db to continue to operate, based on the input signal InDB input from the control device 21 and outputs the brake drive signal SgDB to the gate G of the IGBT 31db. As a result, the semiconductor module 1 continues the normal operation state.

(Operation in Abnormal State when Power Supply Voltage of Pre-Driver is Reduced)

Next, operation in an abnormal state of the semiconductor module 1 when the power supply voltage of the pre-driver 41db is reduced will be described.

When the power supply voltage VDD input to the pre-driver 41db is reduced to a voltage lower than an absolute minimum voltage, the pre-driver 41db is brought into operation in an abnormal state. In this case, the abnormality detection unit 422-2 outputs the operation signal Sca-2 having the high signal level to the protection signal generation unit 423-2 (see FIG. 2). Through this processing, as illustrated in the second row in Table 1, the voltage level at the signal detection terminal Taedb becomes the low level. Thus, the determination unit 421-2 outputs the comparison signal Sc4-2 having the high signal level to the continuation signal generation unit 425-2.

In addition, when the power supply voltage VDD input to the pre-driver 41db is reduced to a voltage lower than the absolute minimum voltage, the signal level of the comparison signal Sc3-2 that is output from the detection unit 422gh becomes the high level, as illustrated in the second row in Table 1. Thus, as illustrated in the second row in Table 1, the signal level of the operation signal Scaa that is output from the NAND gate 425a-2 disposed in the continuation signal generation unit 425-2 becomes the low level, and the signal level of the operation signal Scab that is output from the AND gate 425b-2 disposed in the continuation signal generation unit 425-2 becomes the low level.

As described above, when the power supply voltage VDD is reduced and the pre-driver 41db is operating in an abnormal state, the signal level of the operation signal Sca-2 (see FIG. 2) that is output from the abnormality detection unit 422-2 is the high level, as illustrated in the second row in Table 1. Thus, the continuation signal generation unit 425-2 outputs the suspension signal Sspdb having the high signal level to the pre-driver 41db and does not output the continuation signal Scndb to the pre-driver 41db. Through this processing, the pre-driver 41db generates the brake drive signal SgDB for causing the IGBT 31db to suspend operation independently of the input signal InDB input from the control device 21 and outputs the brake drive signal SgDB to the gate G of the IGBT 31db. As a result, the semiconductor module 1 suspends the operation in the abnormal state.

(Operation in Abnormal State when Overcurrent is Flowing Through IGBT)

Next, operation in an abnormal state of the semiconductor module 1 when overcurrent is flowing through the IGBT 31db will be described.

When current larger than the absolute maximum rated current flows through the IGBT 31db, the IGBT 31db is brought into operation in an abnormal state. In this case, the abnormality detection unit 422-2 outputs the operation signal Sca-2 having the high signal level to the protection signal generation unit 423-2. Through this processing, as illustrated in the third row in Table 1, the voltage level at the signal detection terminal Taedb becomes the low level. Thus, the determination unit 421-2 outputs the comparison signal Sc4-2 having the high signal level to the continuation signal generation unit 425-2.

In addition, since, even when current larger than the absolute maximum rated current flows through the IGBT 31db, the power supply voltage VDD input to the pre-driver 41db is higher than the comparison voltage Vdb3, the signal level of the comparison signal Sc3-2 that is output from the detection unit 422gh becomes the low level, as illustrated in the third row in Table 1. Thus, as illustrated in the third row in Table 1, the signal level of the operation signal Scaa that is output from the NAND gate 425a-2 disposed in the continuation signal generation unit 425-2 becomes the high level, and the signal level of the operation signal Scab that is output from the AND gate 425b-2 disposed in the continuation signal generation unit 425-2 becomes the low level.

As described above, when current larger than the absolute maximum rated current flows through the IGBT 31db and the IGBT31db is operating in an abnormal state, the signal level of the operation signal Sca-2 that is output from the abnormality detection unit 422-2 is the high level, as illustrated in the third row in Table 1. Thus, the continuation signal generation unit 425-2 outputs the suspension signal Sspdb having the high signal level to the pre-driver 41db and does not output the continuation signal Scndb to the pre-driver 41db. Through this processing, the pre-driver 41db generates the brake drive signal SgDB for causing the IGBT 31db to suspend operation independently of the input signal InDB input from the control device 21 and outputs the brake drive signal SgDB to the gate G of the IGBT 31db. As a result, the semiconductor module 1 suspends the operation in the abnormal state.

(Operation in Abnormal State when IGBT is Operating in High-Temperature Condition)

Next, operation in an abnormal state of the semiconductor module 1 when the IGBT 31db is operating in high-temperature condition will be described.

When the IGBT 31db has a temperature higher than the absolute maximum rated temperature, the IGBT 31db is brought into operation in an abnormal state. In this case, the abnormality detection unit 422-2 outputs the operation signal Sca-2 having the high signal level to the protection signal generation unit 423-2. Through this processing, as illustrated in the fourth row in Table 1, the voltage level at the signal detection terminal Taedb becomes the low level. Thus, the determination unit 421-2 outputs the comparison signal Sc4-2 having the high signal level to the continuation signal generation unit 425-2.

In addition, since, even when the IGBT 31db has a temperature higher than the absolute maximum rated temperature, the power supply voltage VDD input to the pre-driver 41db is higher than the comparison voltage Vdb3, the signal level of the comparison signal Sc3-2 that is output from the detection unit 422gh becomes the low level, as illustrated in the fourth row in Table 1. Thus, as illustrated in the fourth row in Table 1, the signal level of the operation signal Scaa that is output from the NAND gate 425a-2 disposed in the continuation signal generation unit 425-2 becomes the high level, and the signal level of the operation signal Scab that is output from the AND gate 425b-2 disposed in the continuation signal generation unit 425-2 becomes the low level.

As described above, when the IGBT 31db operates at a temperature higher than the absolute maximum rated temperature and is operating in an abnormal state, the signal level of the operation signal Sca-2 that is output from the abnormality detection unit 422-2 is the high level, as illustrated in the fourth row in Table 1. Thus, the continuation signal generation unit 425-2 outputs the suspension signal Sspdb having the high signal level to the pre-driver 41db and does not output the continuation signal Scndb to the pre-driver 41db. Through this processing, the pre-driver 41db generates the brake drive signal SgDB for causing the IGBT 31db to suspend operation independently of the input signal InDB input from the control device 21 and outputs the brake drive signal SgDB to the gate G of the IGBT 31db. As a result, the semiconductor module 1 suspends the operation in the abnormal state.

(Operation in Abnormal State when Signal Detection Terminal Detects Protection Signal)

Next, operation in an abnormal state of the semiconductor module 1 when the signal detection terminal Taedb detects, for example, the protection signal SaeZ will be described. Note that when the signal detection terminal Taedb detects the protection signals SaeU, SaeV, SaeW, SaeX, and SaeY, the protection unit 42db also operates in a similar manner to a case where the signal detection terminal Taedb detects the protection signal SaeZ.

When the signal detection terminal Taedb detects the protection signal SaeZ, the voltage level at the signal detection terminal Taedb becomes the low level, as illustrated in the fifth row in Table 1. Thus, the determination unit 421-2 outputs the comparison signal Sc4-2 having the high signal level to the continuation signal generation unit 425-2.

In addition, since, even when the signal detection terminal Taedb detects the protection signal SaeZ, the power supply voltage VDD input to the pre-driver 41db is higher than the comparison voltage Vdb3, the signal level of the comparison signal Sc3-2 that is output from the detection unit 422gh becomes the low level, as illustrated in the fifth row in Table 1. Thus, as illustrated in the fifth row in Table 1, the signal level of the operation signal Scaa that is output from the NAND gate 425a-2 disposed in the continuation signal generation unit 425-2 becomes the high level, and the signal level of the operation signal Scab that is output from the AND gate 425b-2 disposed in the continuation signal generation unit 425-2 becomes the low level.

Since, even when the signal detection terminal Taedb detects the protection signal SaeZ, neither the pre-driver 41db nor the IGBT 31db is operating in an abnormal state, the signal level of the operation signal Sca-2 that is output from the abnormality detection unit 422-2 becomes the low level, as illustrated in the fifth row in Table 1. Thus, the continuation signal generation unit 425-2 outputs the continuation signal Scndb having the low signal level to the pre-driver 41db. Through this processing, the pre-driver 41db generates the brake drive signal SgDB based on the input signal InDB that is input from the control device 21 and outputs the brake drive signal SgDB to the gate G of the IGBT 31db. As a result, the semiconductor module 1 continues operation, based on control by the control device 21.

In both a case where the pre-drivers 41u, 41v, 41w, 41x, 41y, and 41z that are disposed in the gate drive units 4u, 4v, 4w, 4x, 4y, and 4z are operating in an abnormal state and a case where the IGBTs 31u, 31v, 31w, 31x, 31y, and 31z that are driven by the gate drive units 4u, 4v, 4w, 4x, 4y, and 4z are operating in an abnormal state, the signal detection terminal Taedb also detects the protection signals SaeU, SaeV, SaeW, SaeX, SaeY, and SaeZ, respectively. Thus, even when the pre-drivers 41u, 41v, 41w, 41x, 41y, and 41z operating in an abnormal state caused by reduction in the power supply voltage VDD input to the pre-drivers 41u, 41v, 41w, 41x, 41y, and 41z causes the first protection operation to be executed in the protection units 42u, 42v, 42w, 42x, 42y, and 42z, respectively, the semiconductor module 1 does not execute the second protection operation in the protection unit 42db disposed in the brake unit 4db. By this configuration, the semiconductor module 1 is capable of, even when operation of the IGBTs 31u, 31v, 31w, 31x, 31y, and 31z is suspended due to the first protection operation that the protection units 42u, 42v, 42w, 42x, 42y, and 42z execute, respectively, preventing voltage between the positive electrode side and the negative electrode side that is input to the IGBTs 31u, 31v, 31w, 31x, 31y, and 31z from increasing, respectively.

Although detailed description is omitted, the gate drive unit 4z operates in a similar manner to a case where “Sc4-2” illustrated in Table 1 described above is replaced with “Scnz”. Specifically, when the semiconductor module 1 is operating in a normal state, the determination unit 421-1 disposed in the protection unit 42z outputs the continuation signal ScnZ having the low signal level to the pre-driver 41z, as illustrated in the first row of the column “Sc4-2” in Table 1. In contrast, when the power supply voltage VDD input to the pre-driver 41z is lower than the comparison voltage Vz3 (the cross mark in the second row of the column “VDD” in Table 1), when overcurrent is flowing through the IGBT 31z (the cross mark in the third row of the column “Isdb” in Table 1), when the IGBT 31z is operating in a high-temperature condition (the cross mark in the fourth row of the column “Vtdb” in Table 1), or when the signal detection terminal Taez detects a protection signal (“L” in the fifth row of the column “Taedb” in Table 1), the determination unit 421-1 outputs the suspension signal Sspz having the high signal level to the pre-driver 41z. Thus, when at least one of the IGBTs 31u, 31v, 31w, 31x, 31y, and 31z and the pre-drivers 41u, 41v, 41w, 41x, 41y, and 41z operates in an abnormal state, the gate drive unit 4z drives the IGBT 31z in such a way that the IGBT 31z switches to the OFF state.

Since the gate drive units 4u, 4v, 4w, 4x, and 4y have a similar configuration to the gate drive unit 4z, the gate drive units 4u, 4v, 4w, 4x, and 4y drive the IGBTs 31u, 31v, 31w, 31x, and 31y in such a way that the IGBTs 31u, 31v, 31w, 31x, and 31y switch to the OFF state, respectively, when at least one of the IGBTs 31u, 31v, 31w, 31x, 31y, and 31z and the pre-drivers 41u, 41v, 41w, 41x, 41y, and 41z operates in an abnormal state.

As described in the foregoing, the semiconductor module 1 according to the present embodiment includes the IGBTs 31u, 31v, 31w, 31x, 31y, and 31z configured to supply the motor 24 with power, the pre-drivers 41u, 41v, 41w, 41x, 41y, and 41z configured to drive the IGBTs 31u, 31v, 31w, 31x, 31y, and 31z, respectively, and the protection units 42u, 42v, 42w, 42x, 42y, and 42z configured to execute the first protection operation for protecting the IGBTs 31u, 31v, 31w, 31x, 31y, and 31z and the pre-drivers 41u, 41v, 41w, 41x, 41y, and 41z from operation in an abnormal state, respectively. In addition, the semiconductor module 1 according to the present embodiment includes the IGBT 31db configured to adjust the magnitude of voltage input to the IGBTs 31u, 31v, 31w, 31x, 31y, and 31z, the pre-driver 41db configured to drive the IGBT 31db, and the protection unit 42db configured to execute the second protection operation for protecting the IGBT 31db from operation in an abnormal state, and the protection unit 42db executes the second protection operation when the IGBT 31db is operating in an abnormal state and otherwise does not execute the second protection operation regardless of whether or not the protection units 42u, 42v, 42w, 42x, 42y, and 42z are executing the first protection operation.

By this configuration, the semiconductor module 1 is capable of preventing voltage that is input to the IGBTs 31u, 31v, 31w, 31x, 31y, and 31z from increasing even when the first protection operation works in the protection unit 42u, 42v, 42w, 42x, 42y, or 42z.

### Second Embodiment

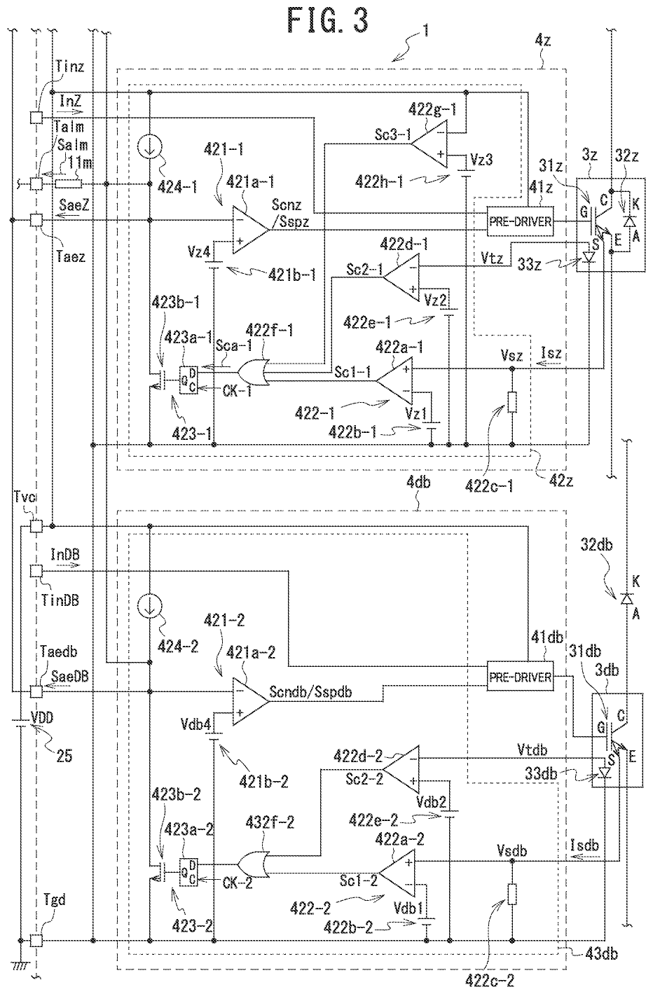

A semiconductor module according to a second embodiment of the present invention will be described using FIG. 3. The semiconductor module according to the present embodiment has an overall configuration similar to the semiconductor module 1 according to the above-described first embodiment. Thus, description of the overall configuration of the semiconductor module according to the present embodiment will be omitted.

### (Configuration of Gate Drive Unit and Brake Unit)

Next, a schematic configuration of gate drive units 4u, 4v, 4w, 4x, 4y, and 4z and a brake unit 4db that are included in a semiconductor module 1 according to the present embodiment will be described using FIG. 3. The gate drive units 4u, 4v, 4w, 4x, 4y, and 4z have the same configuration as one another. Thus, hereinafter, the schematic configuration of the gate drive units 4u, 4v, 4w, 4x, 4y, and 4z will be described using the gate drive unit 4z as an example. FIG. 3 is a circuit diagram illustrative of an example of the schematic configuration of the gate drive unit 4z and the brake unit 4db. In FIG. 3, to facilitate understanding, a semiconductor element 3z that includes an IGBT 31z serving as a drive target of the gate drive unit 4z, a semiconductor element 3db that includes an IGBT 31db serving as a drive target of the brake unit 4db, a freewheeling diode 32db, and a constant voltage source 25 are also illustrated.

Since the gate drive unit 4z in the present embodiment has the same configuration as the gate drive unit 4z in the above-described first embodiment, description thereof will be omitted. The brake unit 4db in the present embodiment has a feature that a protection unit 43db includes neither the detection unit 422gh nor the continuation signal generation unit 425-2 in the above-described first embodiment.

As illustrated in FIG. 3, since the protection unit 43db disposed in the brake unit 4db does not include the continuation signal generation unit 425-2 in the above-described first embodiment, an output terminal of a comparator 421a-2 that is disposed in a determination unit 421-2 is connected to a pre-driver 41db. Thus, the protection unit 43db outputs a comparison signal that is output from the comparator 421a-2 to the pre-driver 41db as a continuation signal Scndb or a suspension signal Sspdb.

In addition, since the protection unit 43db does not include the detection unit 422gh in the above-described first embodiment, an abnormality detection unit 422-2 disposed in the protection unit 43db includes a logical sum gate (OR gate) 432f-2 having a configuration of two inputs and one output. One input terminal of the OR gate 432f-2 is connected to an output terminal of a comparator 422a-2 that is disposed in the abnormality detection unit 422-2. The other input terminal of the OR gate 432f-2 is connected to an output terminal of a comparator 422d-2 that is disposed in the abnormality detection unit 422-2. An output terminal of the OR gate 432f-2 is connected to a signal input terminal (D) of a DFF 423a-2 that is disposed in a protection signal generation unit 423-2.

Thus, the OR gate 432f-2 outputs an operation signal Sca-2 that is obtained by performing a logical sum operation on a comparison signal Sc1-2 that is input from the comparator 422a-2 and a comparison signal Sc2-2 that is input from the comparator 422d-2 to the signal input terminal (d) of the DFF 423a-2.

The protection signal generation unit 423-2, caused by a rise of a clock signal CK-2 when a signal level of the operation signal Sca-2 is a high level, outputs a protection signal SaeDB having a high signal level to a signal detection terminal Taedb. In contrast, the protection signal generation unit 423-2, caused by a rise of a clock signal CK-2 when the signal level of the operation signal Sca-2 is a low level, electrically disconnects the signal detection terminal Taedb from a reference potential terminal Tgd, and the voltage level of the signal detection terminal Taedb is thus maintained at the high level.

A connection state among the protection signal generation unit 423-2, the determination unit 421-2, and the signal detection terminal Taedb in the present embodiment is similar to the connection state among the protection signal generation unit 423-2, the determination unit 421-2, and the signal detection terminal Taedb in the above-described first embodiment. Thus, when the abnormality detection unit 422-2 detects that the IGBT 31db is operating in an abnormal state or when the signal detection terminal Taedb detects at least one of protection signals SaeU, SaeV, SaeW, SaeX, SaeY, and SaeZ, the determination unit 421-2 outputs the suspension signal Sspdb having the high signal level to the pre-driver 41db. In contrast, when the abnormality detection unit 422-2 does not detect that the IGBT 31db is operating in an abnormal state and when the signal detection terminal Taedb does not detect any of the protection signals SaeU, SaeV, SaeW, SaeX, SaeY, and SaeZ, the determination unit 421-2 outputs the continuation signal Scndb having the low signal level to the pre-driver 41db.

To the pre-driver 41db, the output terminal of the OR gate 432f-2 is connected. Thus, the operation signal Sca-2 that the OR gate 432f-2 outputs is input to the pre-driver 41db. The pre-driver 41db monitors whether power supply voltage VDD that is input via a power input terminal Tvc is higher or lower than a predetermined voltage (for example, a voltage that is the same as the comparison voltage Vdb3 in the above-described first embodiment).

When, even when the suspension signal Sspdb is input from the determination unit 421-2, the power supply voltage VDD that is input via the power input terminal Tvc is higher than the predetermined voltage and the signal level of the operation signal Sca-2 that is input from the OR gate 432f-2 is the low level, the pre-driver 41db generates a brake drive signal SgDB, based on an input signal InDB that is input from a signal input terminal TinDB and outputs the brake drive signal SgDB to a gate G of the IGBT 31db. By this configuration, the semiconductor module 1 is capable of continuing operation of the IGBT 31db based on control by a control device 21 (see FIG. 1).

In addition, when the suspension signal Sspdb is input from the determination unit 421-2 and the power supply voltage VDD that is input via the power input terminal Tvc is lower than the predetermined voltage or the signal level of the operation signal Sca-2 that is input from the OR gate 432f-2 is the high level, the pre-driver 41db generates a brake drive signal SgDB that drives the IGBT 31db to an OFF state independently of the input signal InDB that is input from the signal input terminal TinDB and outputs the brake drive signal SgDB to the gate G of the IGBT 31db. By this configuration, the semiconductor module 1 is capable of suspending operation of the IGBT 31db independently of control by the control device 21.

### (Operation of Semiconductor Module)

The brake unit 4db that is disposed in the semiconductor module 1 according to the present embodiment operates in a similar manner to a case where “Sc4-2” illustrated in Table 1 described above is replaced with “Scndb”. Specifically, when the semiconductor module 1 is operating in a normal state, the brake unit 4db according to the present embodiment outputs the continuation signal Scndb having the low signal level to the pre-driver 41db, as illustrated in the first row of the column “Sc4-2” in Table 1. Through this processing, the pre-driver 41db generates the brake drive signal SgDB, based on the input signal InDB that is input from the signal input terminal TinDB and outputs the brake drive signal SgDB to the gate G of the IGBT 31db. As a result, the semiconductor module 1 is capable of continuing operation of the IGBT 31db based on control by the control device 21.

In addition, in the present embodiment, when the power supply voltage VDD input to the pre-driver 41db is lower than the predetermined voltage (the cross mark in the second row of the column “VDD” in Table 1), when overcurrent is flowing through the IGBT 31db (the cross mark in the third row of the column “Isdb” in Table 1), when the IGBT 31db is operating in a high-temperature condition (the cross mark in the fourth row of the column “Vtdb” in Table 1), or when the signal detection terminal Taedb detects a protection signal (“L” in the fifth row of the column “Taedb” in Table 1), the determination unit 421-2 outputs the suspension signal Sspdb having the high signal level to the pre-driver 41db. When the suspension signal Sspdb is input and at least one of when the power supply voltage VDD that is input from the power input terminal Tvc is lower than the predetermined voltage and when the signal level of the operation signal Sca-2 that is input from the abnormality detection unit 422-2 is the high level (i.e., in the case of one of the second to fourth rows in Table 1), the pre-driver 41db generates the brake drive signal SgDB that drives the IGBT 31db to the OFF state independently of the input signal InDB that is input from the signal input terminal TinDB and outputs the brake drive signal SgDB to the gate G of the IGBT 31db. By this configuration, the semiconductor module 1 is capable of suspending operation of the IGBT 31db independently of control by the control device 21.

In contrast, in the present embodiment, when, even when the suspension signal Sspdb is input, the power supply voltage VDD that is input from the power input terminal Tvc is higher than the predetermined voltage and the signal level of the operation signal Sca-2 that is input from the abnormality detection unit 422-2 is the low level (i.e., in the case of the fifth row in Table 1), the pre-driver 41db generates the brake drive signal SgDB, based on the input signal InDB that is input from the signal input terminal TinDB and outputs the brake drive signal SgDB to the gate G of the IGBT 31db. As a result, the semiconductor module 1 is capable of continuing operation of the IGBT 31db based on control by the control device 21.

In the present embodiment, in both a case where the pre-drivers 41u, 41v, 41w, 41x, 41y, and 41z that are disposed in the gate drive units 4u, 4v, 4w, 4x, 4y, and 4z are operating in an abnormal state and a case where the IGBTs 31u, 31v, 31w, 31x, 31y, and 31z that are driven by the gate drive units 4u, 4v, 4w, 4x, 4y, and 4z are operating in an abnormal state, the signal detection terminal Taedb also detects the protection signals SaeU, SaeV, SaeW, SaeX, SaeY, and SaeZ, respectively. Thus, even when the pre-drivers 41u, 41v, 41w, 41x, 41y, and 41z operating in an abnormal state caused by reduction in the power supply voltage VDD input to the pre-drivers 41u, 41v, 41w, 41x, 41y, and 41z causes the first protection operation to be executed in the protection units 42u, 42v, 42w, 42x, 42y, and 42z, respectively, the semiconductor module 1 does not execute the second protection operation in the protection unit 42db disposed in the brake unit 4db. By this configuration, the semiconductor module 1 is capable of, even when operation of the IGBTs 31u, 31v, 31w, 31x, 31y, and 31z is suspended due to the first protection operation that the protection units 42u, 42v, 42w, 42x, 42y, and 42z execute, respectively, preventing voltage between the positive electrode side and the negative electrode side that is input to the IGBTs 31u, 31v, 31w, 31x, 31y, and 31z from increasing.

As described in the foregoing, the semiconductor module 1 according to the present embodiment includes the IGBTs 31u, 31v, 31w, 31x, 31y, and 31z configured to supply the motor 24 with power, the pre-drivers 41u, 41v, 41w, 41x, 41y, and 41z configured to drive the IGBTs 31u, 31v, 31w, 31x, 31y, and 31z, respectively, and the protection units 42u, 42v, 42w, 42x, 42y, and 42z configured to execute the first protection operation for protecting the IGBTs 31u, 31v, 31w, 31x, 31y, and 31z and the pre-drivers 41u, 41v, 41w, 41x, 41y, and 41z from operation in an abnormal state, respectively. In addition, the semiconductor module 1 according to the present embodiment includes the IGBT 31db configured to adjust the magnitude of voltage input to the IGBTs 31u, 31v, 31w, 31x, 31y, and 31z, the pre-driver 41db configured to drive the IGBT 31db, and the protection unit 43db configured to execute the second protection operation for protecting the IGBT 31db from operation in an abnormal state, and the protection unit 43db executes the second protection operation when the IGBT 31db is operating in an abnormal state and otherwise does not execute the second protection operation regardless of whether or not the protection units 42u, 42v, 42w, 42x, 42y, and 42z are executing the first protection operation.

By this configuration, the semiconductor module 1 is capable of preventing voltage that is input to the IGBTs 31u, 31v, 31w, 31x, 31y, and 31z from increasing even when the first protection operation works in the protection unit 42u, 42v, 42w, 42x, 42y, or 42z.

The present invention is not limited to the above-described embodiments, and various modification are possible.

Although the continuation signal generation unit that is disposed in the semiconductor module according to the above-described first embodiment includes a NAND gate, an AND gate, and an OR gate, the present invention is not limited thereto. The continuation signal generation unit may have a different configuration as long as, when a signal detection terminal corresponding to a brake unit detects a protection signal, the continuation signal generation unit can generate a continuation signal having the same signal level as a continuation signal that is generated when the semiconductor module is normally operating.

The technical scope of the present invention is not limited to the illustrated and described exemplary embodiments, but includes all embodiments causing an effect equivalent to the object of the present invention. Furthermore, the technical scope of the present invention is not limited to combinations of features of the inventions defined by the claims, but can be defined by all desired combinations of specific features among all the disclosed features.

### REFERENCE SIGNS LIST

1 Semiconductor module
3db, 3u, 3v, 3w, 3x, 3y, 3z Semiconductor element
4db Brake unit
4u, 4v, 4w, 4x, 4y, 4z Gate drive unit
11m, 11u, 11v, 11w, 26 Resistance element
21 Control device
22 AC power unit
23 Smoothing capacitor
24 Motor
25 Constant voltage source
31db, 31u, 31v, 31w, 31x, 31y, 31z IGBT
32db, 32u, 32v, 32w, 32x, 32y, 32z Free wheeling diode
33db, 33u, 33v, 33w, 33x, 33y, 33z Temperature detection element
41db, 41u, 41v, 41w, 41x, 41y, 41z Pre-driver
42db, 42u, 42v, 42w, 42x, 42y, 42z, 43db Protection unit
421-1, 421-2 Determination unit
421a-1, 421a-2, 422a-1, 422a-2, 422d-1, 422d-2, 422g-1,
422g-2 Comparator
421b-1, 421b-2, 422b-1, 422b-2, 422e-1, 422e-2, 422h-1,
422h-2 Comparison voltage generation unit
422-1, 422-2 Abnormality detection unit
422c-1, 422c-2, 422c-3 Current detection unit
422f-1, 422f-2, 425c-2, 432f-2 OR gate
422gh Detection unit
423-1, 423-2 Protection signal generation unit
423a-1, 423a-2 DFF
423b-1, 423b-2 Transistor
424-1, 424-2 Constant current source
425-2 Continuation signal generation unit
425a-2 NAND gate
425b-2 AND gate
InDB, InU, InV, InW, InX, InY, InZ Input signal
Isdb, Isu, Isv, Isw, Isx, Isy, Isz Detected current
Ln Negative electrode-side line
Lp Positive electrode-side line
S Current detection element
SaeDB, SaeU, SaeV, SaeW, SaeX, SaeY, SaeZ Protection
signal
Salm, Salu, Salv, Salw Alarm signal
Sc1-1, Sc1-2, Sc2-1, Sc2-2, Sc3-1, Sc3-2, Sc4-2
Comparison signal
Sca-1, Sca-2, Scaa, Scab Operation signal
Scndb, Scnz Continuation signal
SgDB Brake drive signal
SgU, SgV, SgW, SgX, SgY, SgZ Gate drive signal
Sspdb, Sspz Suspension signal
Taedb, Taeu, Taev, Taew, Taex, Taey, Taez Signal detection terminal
Talm, Talu, Talv, Talw Alarm signal output terminal
Tdb Regenerative power terminal
Tgd Reference potential terminal
Tgdu, Tgdv, Tgdw Upper-phase reference potential terminal
TinDB, TinU, TinV, TinW, TinX, TinY, TinZ Signal input terminal
Tn Negative electrode-side power input terminal
Tp Positive electrode-side power input terminal
TU U-phase output terminal
TV V-phase output terminal
Tvc, Tvcu, Tvcv, Tvcw Power input terminal
TW W-phase output terminal
Vdb1, Vdb2, Vdb3, Vdb4, Vz1, Vz2, Vz3 Comparison voltage
Vz4 Comparison voltage
VCC, VDD Power supply voltage
Vsz, Vsdb, Vtdb, Vtu, Vtv, Vtw, Vtx, Vty, Vtz Detected voltage

1. A semiconductor module comprising:
a first switching element configured to supply a load with power;
a first drive unit configured to drive the first switching element;
a first protection unit configured to execute first protection operation protecting the first switching element and the first drive unit from operation in an abnormal state;
a second switching element configured to adjust magnitude of voltage input to the first switching element;
a second drive unit configured to drive the second switching element; and
a second protection unit configured to execute second protection operation protecting the second switching element from operation in an abnormal state,
wherein the second protection unit executes the second protection operation when the second switching element is operating in an abnormal state and otherwise does not execute the second protection operation regardless of whether or not the first protection unit is executing the first protection operation.

2. The semiconductor module according to claim 1, wherein the first protection unit executes the first protection operation when at least one of the first switching element and the first drive unit is operating in an abnormal state or when the second protection unit is executing the second protection operation.

3. The semiconductor module according to claim 2 further comprising:
a first signal detection terminal connected to the first protection unit and configured to detect a second protection signal indicating whether or not the second protection operation is executed; and
a second signal detection terminal connected to the first signal detection terminal and the second protection unit and configured to detect a first protection signal indicating whether or not the first protection operation is executed,
wherein the first protection unit outputs the first protection signal to the first signal detection terminal, and
the second protection unit outputs the second protection signal to the second signal detection terminal.

4. The semiconductor module according to claim 3, wherein
the first protection unit includes:
a first abnormality detection unit configured to detect whether or not at least one of the first switching element and the first drive unit is operating in an abnormal state;
a first protection signal generation unit configured to generate the first protection signal, based on a detection result by the first abnormality detection unit; and
a first determination unit configured to determine whether or not the second protection operation is executed, using the second protection signal detected by the first signal detection terminal, and
the second protection unit includes:
a second abnormality detection unit configured to detect whether or not the second switching element is operating in an abnormal state;
a second protection signal generation unit configured to generate the second protection signal, based on a detection result by the second abnormality detection unit; and
a second determination unit configured to determine whether or not the first protection operation is executed, using the first protection signal detected by the second signal detection terminal.

5. The semiconductor module according to claim 1, wherein the second protection unit executes the second protection operation to protect the second drive unit from operation in an abnormal state in addition to protecting the second switching element.

6. The semiconductor module according to claim 5 further comprising:
a first signal detection terminal connected to the first protection unit and configured to detect a second protection signal indicating whether or not the second protection operation is executed; and
a second signal detection terminal connected to the first signal detection terminal and the second protection unit and configured to detect a first protection signal indicating whether or not the first protection operation is executed,
wherein the first protection unit outputs the first protection signal to the first signal detection terminal, and
the second protection unit outputs the second protection signal to the second signal detection terminal.

7. The semiconductor module according to claim 6, wherein
the first protection unit includes:
a first abnormality detection unit configured to detect whether or not at least one of the first switching element and the first drive unit is operating in an abnormal state;
a first protection signal generation unit configured to generate the first protection signal, based on a detection result by the first abnormality detection unit; and
a first determination unit configured to determine whether or not the second protection operation is executed, using the second protection signal detected by the first signal detection terminal, and
the second protection unit includes:
a second abnormality detection unit configured to detect whether or not the second switching element is operating in an abnormal state;
a second protection signal generation unit configured to generate the second protection signal, based on a detection result by the second abnormality detection unit; and
a second determination unit configured to determine whether or not the first protection operation is executed, using the first protection signal detected by the second signal detection terminal.

8. The semiconductor module according to claim 7 further comprising:
a detection unit disposed in the second abnormality detection unit and configured to detect whether or not the second drive unit is operating in an abnormal state; and
a continuation signal generation unit configured to generate a continuation signal for causing the second switching element to continue to operate, based on a detection result by the first abnormality detection unit, a detection result by the detection unit, and a determination result by the second determination unit and output the generated continuation signal to the second drive unit.

9. The semiconductor module according to claim 8, wherein the continuation signal generation unit generates the continuation signal having a same signal level regardless of a detection result by the first abnormality detection unit.

10. The semiconductor module according to claim 3, wherein
the semiconductor module includes a plurality of pairs of the first protection unit and the first signal detection terminal, and
each of a plurality of the first signal detection terminals also detects the first protection signal based on the first protection operation in one of the remaining first protection units with which the first signal detection terminal does not pair.

11. The semiconductor module according to claim 4, wherein
the semiconductor module includes a plurality of pairs of the first protection unit and the first signal detection terminal, and
each of a plurality of the first signal detection terminals also detects the first protection signal based on the first protection operation in one of the remaining first protection units with which the first signal detection terminal does not pair.

12. The semiconductor module according to claim 6, wherein
the semiconductor module includes a plurality of pairs of the first protection unit and the first signal detection terminal, and
each of a plurality of the first signal detection terminals also detects the first protection signal based on the first protection operation in one of the remaining first protection units with which the first signal detection terminal does not pair.

13. The semiconductor module according to claim 9, wherein
the semiconductor module includes a plurality of pairs of the first protection unit and the first signal detection terminal, and
each of a plurality of the first signal detection terminals also detects the first protection signal based on the first protection operation in one of the remaining first protection units with which the first signal detection terminal does not pair.
